(19) United States
(12) Patent Application Publication
(10) Pub. No.: US 2006/0027936 A1
(43) Pub. Date: Feb. 9, 2006

(54) Method for processing base

(75) Inventors: Masataka Mizukoshi, Kawasaki (JP); Nobuhiro Imaizumi, Kawasaki (JP); Yoshikatsu Ishizuki, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/017,875

(22) Filed: Dec. 22, 2004

(30) Foreign Application Priority Data
Aug. 5, 2004 (JP) 2004-229921

(51) Int. Cl. H01L 29/40; H01L 21/44

(52) U.S. Cl. 257/781; 438/612; 438/675

(57) ABSTRACT

Electrodes and an insulating film are both formed of materials which have characteristics that they are solid and do not exhibit adhesiveness at a room temperature, exhibit adhesiveness at and above a first temperature higher than this, and are cured at and above a second temperature higher than this. Planarication processing is carried out by performing cutting with a hard cutting tool made of diamond and the like so that surfaces film the electrodes and a surface of the insulating film become continuously planar.

### CROSS-REFERENCE TO RELATED APPLICATIONS

This application is based upon and claims the benefit of priority from the prior Japanese Patent Application No. 2004-229921, filed on Aug. 5, 2004, the entire contents of which are incorporated herein by reference.

### BACKGROUND OF THE INVENTION

1. Field of the Invention

The present invention relates to a joined base (semiconductor device) composed of a pair of bases (combinations of a semiconductor chip and a circuit board, a semiconductor chip and a semiconductor chip, and so on) connected to each other with electrodes, and a method for processing a base (method for manufacturing the semiconductor device), and is preferably applied in particular to a so-called RFID, a Smart Card, and the like.

2. Description of the Related Art

Recently, as an electronic device becomes smaller and thinner, high density assembly of electronic components is increasingly required, and flip-chip mounting, in which electronic components such as a semiconductor chip and the like in bare state are directly mounted on a substrate, has been adopted. On an electrode of the semiconductor chip used in the flip-chip mounting, there is formed a projecting electrode, and the projected electrode and a wiring on a circuit board are electrically joined.

Technologies for forming metal terminals includes, as typical examples thereof, an electrolytic plating method, an electroless plating method, a solder-dip method, a solder print transfer method, a printing method, and so on.

By the electrolytic plating method, a specimen is set in plating solution and with electric currents being supplied to seed electrodes connected to electrode pads, metal terminals are collectively formed on the electrode pads patterned by photo process. Characteristically, it is possible to form the metal terminals of several μm to several 10 μm pitch with high aspect ratio by using high resolution resist. As materials of the metal terminal by the electrolytic plating method, gold, solder and the like are used.

By the electroless plating method, the metal terminals can be collectively formed on arbitrary metal pads. Characteristically, plating grows isotropically, and the photo process is unnecessary.

By the solder dip method, a specimen having electrode pads is dipped in a molten low-melting metal consisting mainly of tin (Sn), lead (Pb) or the like, and then pulled out. Hereby, the low-melting metal moistening only tops of the electrode pads by surface tension cools and solidifies to form the metal terminals.

By the solder print transfer method, a low-melting metal consisting mainly of tin (Sn), lead (Pb) or the like is turned into a paste and applied by printing to hollow portions, in a metal plate, formed in positions corresponding to electrode pads. Then, after the low-melting metal is reflown and made to spherical electrodes, they are collectively transferred to the electrode pads on a specimen.

By the printing method, a metal paste is printed with use of a fixed mask. Moreover, a material mixed of an organic material and metal powder, such as a conductive silver paste, is used for low-cost projecting electrodes.

Furthermore, recently a following method is conceived as a method for joining metal terminals of a semiconductor chip and metal terminals of a circuit board, in flip chip mounting.

In Patent Document 1, there is disclosed an art in which a surface of a semiconductor chip is covered by an insulating resin having adhesiveness, and the insulating resin and metal terminals are processed by grinding to be a uniform flat surface.

In Patent Document 2, there is disclosed an art in which a surface of a semiconductor chip having metal electrodes is covered by an insulating resin, and a surface of the insulating resin is polished to reveal the metal electrodes, thereafter the metal terminals are faced to each other and joined by thermocompression.

In Patent Document 3, there is disclosed an art in which a semiconductor chip and a circuit board are pressure-contacted via a thermosetting resin, with viscosity of the thermosetting resin being kept so that the thermosetting resin does not gelate, ultrasonic wave vibrations are applied so that a solid state diffusion layer is formed on a joint portion of metal terminals, to join them.

In Patent Document 4, there is disclosed an art in which a semiconductor chip and a circuit board are pressure-contacted via a thermosetting resin, with a viscosity range in which the thermosetting resin is kept being narrower compared with that in Patent Document 3, a solid state diffusion layer is formed on a joint portion of metal terminals, to join them.

In Patent Document 5, there is disclosed an art in which, when a semiconductor chip and a circuit board are joined via an insulating resin having adhesiveness, an infrared-opaque positioning mark is in advance formed on a part other than metal terminals of the semiconductor chip, and by detecting this positioning mark with an infrared camera, alignment is carried out.

In Patent Document 6, there is disclosed an art in which, when a semiconductor chip and a circuit board are joined via a thermosetting resin, metal terminals (conductor patterns) of the circuit board are elastically deformed by pressure, and in pressed state the thermosetting resin is cured and join them.

(Patent Document 1)
Japanese Patent Application Laid-Open No. Hei 9-237806

(Patent Document 2)
Japanese Patent Application Laid-Open No. Hei 11-274241

(Patent Document 3)
Japanese Patent Application Laid-Open No. 2001-298146

(Patent Document 4)
Japanese Patent Application Laid-Open No. 2003-258034

(Patent Document 5)
Japanese Patent Application Laid-Open No. 2002-252245

(Patent Document 6)
Japanese Patent Application Laid-Open No. 2001-144141

When the above-described conventional arts are applied to formation of metal terminals of an electronic component such as an LSI and a mounting step thereof, following problems arise.

For example, with regard to the art disclosed in the above Patent Document 1, the metal terminals and the insulating resin on the surface of the semiconductor chip are processed by the grinding to be the uniform flat surface. If an object to be ground is a soft material such as a resin, there arises a problem (burn) such that dust from the grinding adheres to a surface of a grinding disk and the grinding becomes impossible. There also arises another problem such that a resin or a metal being a base material of the grinding disk contaminates the surface of the resin being the object to be ground.

With regard to the art disclosed in the above Patent Document 2, the metal terminals and the insulating resin on the surface of the semiconductor chip are processed by the polishing to be the uniform flat surface. In such a case of planarization by the polishing, there arises a problem that, if two or more types of materials with different hardnesses are polished, a level difference called dishing occurs on a polished surface and the flat surface is not obtained. There arise other problems such that water and alcohols used in the polishing affect and such that abrasive grains used for polishing dig into a surface of an object to be polished and adversely affects it.

With regard to the art disclosed in Patent Document 3, after the thermosetting resin is applied on a substrate on which bumps are formed, the solid state diffusion layer is formed on surfaces of the bumps by the ultrasonic wave vibrations and to carry out joining. However, since the joining is carried out without the planarization processing such as the polishing, for secure joining, it is necessary to apply substantial load, causing a problem that the semiconductor chip is significantly damaged thereby.

Also with regard to the arts disclosed in Patent Document 4 and Patent Document 6, as in the art of Patent Document 3, for the secure joining, it is necessary to apply substantial load, causing a problem that the semiconductor chip is significantly damaged thereby.

With regard to the art disclosed in Patent Document 5, although accuracy of joining position of the semiconductor chip and the circuit board can be improved, particular innovation is not shown about the joining.

### SUMMARY OF THE INVENTION

An object of the present invention is to solve the above problems and provide a joined base which is low in cost, has an even and smooth height, enables forming of metal terminals connected at a low load, enables mounting at low damage, and has high reliability to prevent unauthorized alteration by detaching the base, and a method for processing the base.

A method for processing a base according to the present invention includes the steps of: forming first electrodes with projecting shapes, on a surface of a first base, with a conductive material exhibiting adhesiveness at and above a first temperature; coating an insulating film made of an insulating material exhibiting adhesiveness at and above a second temperature, on a surface of the first base including on the first electrodes; performing cutting with a cutting tool so that surfaces of the first electrodes and a surface of the insulating film are processed to be continuously planar, while temperature is kept under a lower value of the first temperature and the second temperature; disposing a second base on which second electrodes corresponding to the first electrodes are formed, on the surface on which the first electrodes are formed, of the first base, in a manner that the first base and the second base face each other; and raising temperature to and above a higher value of the first temperature and the second temperature, so that the first base and the second base are connected by the insulating film, and so that the first electrodes and the second electrodes are electrically connected.

A concrete example of this method for processing is described below.

1. The conductive material in paste form is supplied on the base 1 and the projecting electrodes are formed (for example, by a printing method).

2. The conductive material is semi-cured (for example, at 80° C. for 30 minutes).

3. The insulating material is coated.

4. The insulating material is semi-cured (for example, at 110° C. for 30 minutes).

5. The cutting is performed (for example, at 50° C.)

6. The base 1 and the base 2 are connected (for example, at 150° C. for 5 seconds).

As another mode, a method for processing a base according to the present invention includes the steps of: forming an insulating film on a first base by depositing an insulating material exhibiting adhesiveness at and above a second temperature; forming openings in the insulating film; forming first electrodes by depositing a conductive material exhibiting adhesiveness at and above a first temperature in a manner that the conductive material fills inside the openings; performing cutting with a cutting tool so that surfaces of the first electrodes and a surface of the insulating film are processed to be continuously planar, while temperature is kept under a lower value of the first temperature and the second temperature; and raising temperature to and above a higher value of the first temperature and the second temperature, and making the first base face a second base on a surface of which a plurality of second electrodes are formed in a manner that the first electrodes contact the second electrodes, so that the first base and the second base are connected by the insulating film and so that an electric connection is generated between the first electrodes and the second electrodes.

A concrete example of this method for processing is described below.

1. The insulating adhesive is deposited (for example, by a spin-coat method).

2. The insulating adhesive is semi-cured (for example, at 110° C. for 30 minutes).

3. The openings are formed in the insulating adhesive (for example, by exposure/development).

4. The conductive material is filled into the openings (for example, by a printing method).

5. The conductive material is semi-cured (for example, at 80° C. for 30 minutes).

6. The cutting is performed (for example, at 50° C.).

7. The base 1 and the base 2 are connected (for example, at 190° C. for 5 seconds).

As still another mode, a method for processing a base according to the present invention includes the steps of: forming first electrodes with projecting shapes, on a surface of a first base, with a conductive material exhibiting adhesiveness at and above a first temperature; coating a first insulating film made of a first insulating material exhibiting adhesiveness at and above a second temperature, on a surface of the first base, in a manner to be lower than heights of the first electrodes; coating a second insulating film made of a second insulating material exhibiting adhesiveness at and above a third temperature, on the first insulating film including on the first electrode; performing cutting with a cutting tool so that surfaces of the first electrodes and a surface of the second insulating film are processed to be continuously planar, while temperature is kept under a lowest value of the first temperature, the second temperature, and the third temperature; disposing a second base on which second electrodes corresponding to the first electrodes are formed, on the surface on which the first electrodes are formed, of the first base, in a manner that the first base and the second base face each other; and raising temperature to and above a highest value of the first temperature, the second temperature, and the third temperature, so that the first base and the second base are connected by the insulating films made of the first insulating film and the second insulating film, and so that the first electrodes and the second electrodes are electrically connected.

A concrete example of this method for processing is described below.

1. The conductive material in paste form is supplied on the base 1 and the projecting electrodes are formed (for example, by a printing method).

2. The conductive material is semi-cured (for example, at 80° C. for 30 minutes).

3. The first insulating material is coated.

4. The first insulating material is semi-cured (for example, at 110° C. for 30 minutes).

5. The second insulating material is coated.

6. The second insulating material is semi-cured (for example, at 100° C. for 30 minutes).

7. The cutting is performed (for example, at 50° C.).

8. The base 1 and the base 2 are connected (for example, at 150° C. for 5 seconds).

### BRIEF DESCRIPTION OF THE DRAWINGS

FIG. 1A to FIG. 1G are schematic sectional views showing a method for manufacturing a semiconductor device according to a first embodiment step by step;

FIG. 2 is a schematic view showing an example of a cutting apparatus;

FIG. 3A to FIG. 3H are schematic sectional views showing a method for manufacturing a semiconductor device according to a second embodiment step by step;

FIG. 4A to FIG. 4F are schematic sectional views showing a method for manufacturing a semiconductor device according to a third embodiment step by step;

FIG. 5 is a schematic view showing a method for manufacturing an RFID according to a fourth embodiment step by step;

FIG. 6 is a schematic view showing the method for manufacturing the RFID according to the fourth embodiment, continued from FIG. 5;

FIG. 7 is a schematic view showing the method for manufacturing the RFID according to the fourth embodiment, continued from FIG. 6;

FIG. 8 is a schematic view showing the method for manufacturing the RFID according to the fourth embodiment, continued from FIG. 7;

FIG. 9 is a schematic view showing the method for manufacturing the RFID according to the fourth embodiment, continued from FIG. 8;

FIG. 10 is a schematic view showing the method for manufacturing the RFID according to the fourth embodiment, continued from FIG. 9;

FIG. 11 is a schematic view showing the method for manufacturing the RFID according to the fourth embodiment, continued from FIG. 10;

FIG. 12 is a schematic view showing the method for manufacturing the RFID according to the fourth embodiment, continued from FIG. 11;

FIG. 13 is a schematic view showing the method for manufacturing the RFID according to the fourth embodiment, continued from FIG. 12;

FIG. 14 is a schematic view showing the method for manufacturing the RFID according to the fourth embodiment, continued from FIG. 13; and

FIG. 15A and FIG. 15B are schematic views showing the method for manufacturing the RFID according to the fourth embodiment, as FIG. 14 is.

### DETAILED DESCRIPTION OF THE PREFERRED EMBODIMENTS

Basic Gist of Present Invention

To the present invention, as a method for planarizing surfaces of numerous electrodes formed on a base inexpensively, fast, and simultaneously, cutting with a hard cutting tool made of diamond and the like is applied, instead of a CMP method. According to this cutting, even in such a case that the electrodes are buried and formed in an insulating film on a surface of the base, a metal and the insulating film can be continuously cut on the base simultaneously, without depending on a grinding speed and the like of the metal and the insulator as in the CMP method. Therefore, it is possible to uniformly planarize the both as a whole, without generating a dishing and the like.

Additionally, since the diamond excels at heat conductivity, it lets off friction heat generated in the cutting to the outside, preventing the insulator from melting.

Based on the above, it has been earnestly studied to securely connect the bases without increasing or complicating a manufacturing process. It has been attempted, for example, to use an insulating material having adhesiveness (underfill, insulating sheet, insulating film, or the like) as the insulating film where the electrodes are buried, to planarize for example a surface of a first base (surfaces of electrodes and an insulating film) by cutting, and to connect the bases. More specifically, the insulating film is used as a sealant to bury and protect the electrodes and also used as a connection-reinforcing material in connecting the electrodes of the bases. In this case, the insulating film is not removed after the cutting, and adhesiveness thereof is used when the electrodes are faced to each other and connected.

In this attempt, as the insulating material for the insulating film, there is used an insulating material which exhibits adhesiveness at and above a first temperature and loses adhesiveness at and above a second temperature higher than this. More specifically, there is used the insulating material which has a characteristic that it is solid and does not exhibit adhesiveness at a room temperature, softens and exhibits adhesiveness when reaching the first temperature, and solidifies and loses adhesiveness when reaching the second temperature. Additionally, as a conductive material for the electrodes, there is used a material which exhibits adhesiveness at and above a third temperature and loses adhesiveness at and above a fourth temperature higher than this. More specifically, there is used the conductive material which has a characteristic that it is solid and does not exhibit adhesiveness at the room temperature, softens and exhibits adhesiveness when reaching the third temperature, and solidifies and loses adhesiveness when reaching the fourth temperature.

Then, after planarization processing by cutting is carried out at a temperature lower than a lower value of the first temperature and the second temperature, the electrodes of the first base (for example, a diced semiconductor chip) and electrodes of a second base (for example, a circuit board or a semiconductor chip) corresponding thereto are faced and contacted at and above a higher value of the first temperature and the second temperature, so that the bases are connected by the insulating material exhibiting adhesiveness, and so that the conductive material (electrodes made of the conductive material) exhibiting adhesiveness, of the first base, and the electrodes of the second base are connected.

Subsequently, the insulating material filling between the electrodes of the first base and the second base is solidified, and the conductive material connected to the electrodes of the second base is solidified, at and above a higher value of the second temperature and the fourth temperature. It has been verified that secure connection between the bases and good electric connection between the electrodes are obtained hereby. However, there are identified a phenomenon such that during the cutting with the cutting tool, the insulating material softens since temperature becomes at and above the first temperature due to friction heat of the cutting tool, and a coating is formed on surfaces of the electrodes which are also soften.

In view of this phenomenon, the present inventor has conceived to process the conductive material and the insulating material into a continuous plane and carry out a connection by controlling temperatures to which the insulating film and the electrodes are raised by friction heat generated in the cutting with the cutting tool to be under the lower value of softening temperatures for the insulating material and the conductive material, i.e. the first temperature and the second temperature.

For example, in the semiconductor chip, when electrodes made of Ag paste which softens at 110° C. (the first temperature is 110° C.) and an insulating film made of epoxy resin which softens at 80° C. (the first temperature is 80° C.) are simultaneously planarized by the cutting with the cutting tool, it is possible to prevent the Ag paste and the epoxy resin from softening by using the cutting tool with excellent heat conductivity such as diamond and controlling a cutting speed of the cutting tool, a cutting depth, and the like so that a temperature to which the insulating film is raised by friction heat is kept at and under 80° C. These Ag paste electrodes are made face gold (Au) plated electrodes for example of the circuit board, and pressed at and above the second temperature for example at 150° C. at a load of approximately 10 gf per electrode for a predetermined time, so that the Ag paste electrodes are cured and adhere to the Au plated electrodes and at the same time the surrounding epoxy resin is cured. Hereby, a secure connection of the epoxy resin and good electric connection between the electrodes are obtained.

As described above, according to the present invention, in the first base of the semiconductor chip and the like, the electrodes made of the conductive material with the above-described characteristic are covered by the insulating film made of the insulating material with the above-described characteristic, and planarized by the cutting. Hereby, it becomes possible that a role of mechanical adhesion is assigned to the insulating material and a role of an electric connection is assigned to the conductive material, when the first base is joined with the second base such as the circuit board. Therefore, it is possible to form a joined base by inexpensive materials and methods which cannot be conventionally used.

Additionally, according to the present invention, a position of an LSI on a surface of the base can be recognized by differences of color tones and reflectivities of the electrodes and the insulating film which appear on the cut plane of the first base. Therefore, an insulating material opaque to visible light can be used as the insulating film. In general, the insulating material which has excellent adhesive intensity and is capable of controlling a thermal expansion coefficient is opaque.

Further, in view of obtaining securer joining between the first base such as the semiconductor chip and the second base such as the circuit board, as well as preventing contents of a ROM and the like from being changed, the present inventor has conceived to form the insulating film of two layers by using two kinds of insulating materials which have characteristics described above. Incidentally, for description convenience, wordings such as “second temperature” are used in descriptions below, but they are unrelated to the “second temperature” and the like in the above example of forming the insulating film of a single layer.

There are used: a conductive material which exhibits adhesiveness at and above a first temperature and loses adhesiveness at and above a sixth temperature higher than this, more specifically, the conductive material which has a characteristic that it is solid and does not exhibit adhesiveness at a room temperature, softens and exhibits adhesiveness when reaching the first temperature, and solidifies and loses adhesiveness when reaching the sixth temperature; a first insulating material which exhibits adhesiveness at and above a second temperature and loses adhesiveness at and above a fourth temperature higher than this, more specifically, the first insulating material which has a characteristic that it is solid and does not exhibit adhesiveness at the room temperature, softens and exhibits adhesiveness when reaching the second temperature, and solidifies and loses adhesiveness when reaching the fourth temperature; and a second insulating material which exhibits adhesiveness at and above a third temperature and loses adhesiveness at and above a fifth temperature higher than this, more specifically the second insulating material which has a characteristic that it is solid and does not exhibit adhesiveness at the room temperature, softens and exhibits adhesiveness when reaching the third temperature, and solidifies and loses adhesiveness when reaching the fifth temperature. In a first base, a first insulating film is formed by filling the first insulating material between electrodes in a manner to be lower than heights of the electrodes, and a second insulating film is formed by depositing the second insulating material on the first insulating film in a manner to cover the electrodes. Here, the first insulating material is the material which exhibits secure adhesive intensity with the first base at and above the fourth temperature, and the second insulating material is the material which exhibits adhesive intensity with both the first insulating material and the second base at and above the fifth temperature.

In this state, while friction heat is taken into consideration as in the above, planarization processing is carried out by cutting with a cutting tool, with temperature being kept under a lowest value of the first temperature, the second temperature, and the third temperature. At this time, flat surfaces of the electrodes and the second insulating film appear from the cut surface. Subsequently, the electrodes of the first base and the corresponding electrodes of the second base are made face and contact each other at and above a highest temperature of the first temperature, the second temperature, and the third temperature, so that the bases are connected by the second insulating material exhibiting adhesiveness, and so that the conductive material (electrodes made of the conductive material) exhibiting adhesiveness, of the first base, and the electrodes of the second base are connected. Since the second insulating material excels at adhesiveness to the first insulating material and the second base, the bases are joined more securely.

Then, the first and the second insulating materials filling between the first base and the electrodes of the second base are solidified at and above a highest value of the fourth, the fifth, and the sixth temperature, as well as the conductive material connected to the electrodes of the second base is solidified. Hereby, a secure connection between the bases and a good electric connection between the electrodes are obtained. Additionally, in this case, it is possible to choose as the first insulating material a material having strong adhesiveness to the first base, so that a range of choices for the material is expanded.

Hereinafter, specific embodiments to which the present invention is applied will be described in detail with reference to the drawings. Incidentally, for description convenience, wordings such as “second temperature” are used in describing the following embodiments, but they are unrelated to the “second temperature” and the like stated in the above description.

### First Embodiment

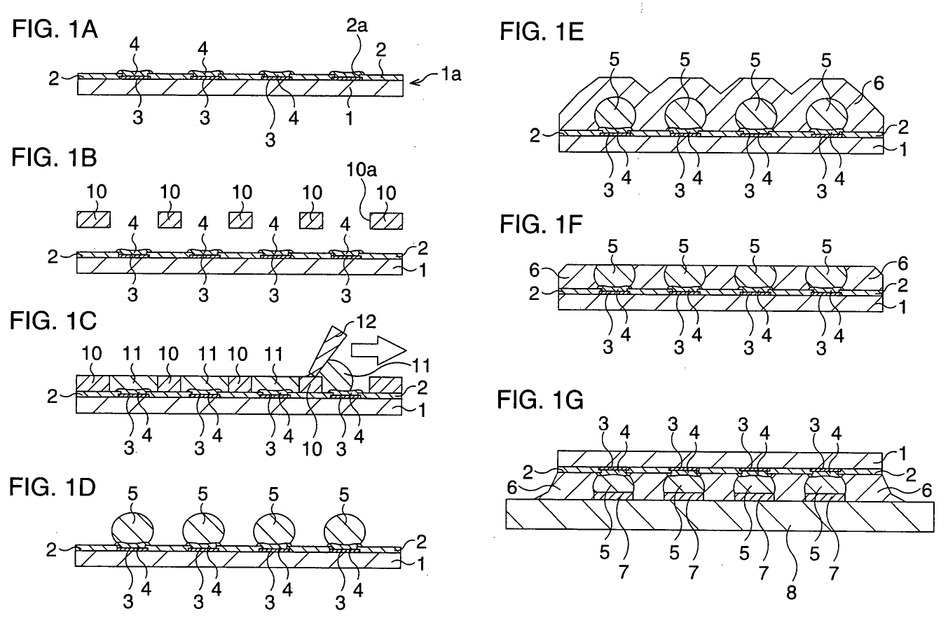

FIG. 1 is a schematic sectional view showing a method for manufacturing a semiconductor device according to a first embodiment step by step.

Here, a first base is a semiconductor chip which is diced from a semiconductor wafer and on a principal surface of which electrode terminals are disposed, and a second base is a circuit board on which the semiconductor chip is to be flip-chip mounted. Now, a case that the semiconductor chip is mounted on the circuit board is described. The circuit board includes an insulating substrate formed of glass epoxy and the like, and a conductive layer formed on the surface and/or inside thereof. On its mounting surface for the semiconductor chip, there are disposed electrode terminals corresponding to electrode terminals of the semiconductor chip to be mounted.

In the present embodiment, after a surface, i.e., a mounted surface, of the semiconductor chip is planarized by cutting, the electrode terminals of the semiconductor chip and the electrode terminals of the circuit board are faced and connected.

In FIG. 1A, a semiconductor chip 1a includes, on one principal surface thereof, a semiconductor substrate 1 made of silicon (Si) on which a logic circuit and/or a storage circuit and the like (not shown) constituted with a functional element such as an MOS transistor and a passive element such as a capacitor element and so on are/is formed, an insulating layer 2 made of silicon oxide and the like which is disposed to cover the one principal surface of the semiconductor substrate 1, openings 2a selectively disposed in the insulating layer 2, and electrode layers disposed in the opening 2a parts.

This electrode layer includes a foundation metal layer composed of a multi-layered body of a metal layer 3 disposed on an aluminum (Al) electrode pad (not shown) which is lead out from the functional element part and/or the passive element part, and a metal layer 4 disposed on the metal layer 3. Nickel (Ni) and gold (Au) are formed by being sequentially deposited by an electroless plating method. As a material of the metal layer 3, there is used a metal such as aluminum (Al), copper (Cu), gold (Au), silver (Ag), nickel (Ni) or tungsten (W), or an alloy of these. As a material of the metal layer 4, there is used a metal such as gold (Au), tin (Sn), copper (Cu) silver (Ag), nickel (Ni), or tungsten (W), or an alloy of these.

Subsequently, as shown in FIG. 1B, on the semiconductor chip 1a, a metal mask 10 is aligned and formed in a manner that openings 10a thereof correspond to the electrode layer so that surfaces of the electrode layers appear.

Subsequently, as shown in FIG. 1C, an Ag paste 11 (for example, brand name EN4072 of Hitachi Chemical Co., Ltd.) is used as a conductive material, and the Ag paste 11 is stamped by a printing method with a squeezee 12 to fill inside the openings 10a of the metal mask 10. This Ag paste 11 has a characteristic that after semi-cured it is solid and does not exhibit adhesiveness at a room temperature, exhibits adhesiveness at and above a first temperature higher than this, and is cured at and above a third temperature higher than this. Here, for example, the first temperature is approximately 80° C., and the third temperature is approximately 130° C. Incidentally, as the conductive material in the present embodiment, in addition to the Ag paste, an Au paste, a Pd paste, a Pt paste, or an alloy paste of these can be used.

Subsequently, as shown in FIG. 1D, with the metal mask 10 being removed, the Ag paste 11 is semi-cured (so-called B-stage cured) at a temperature of approximately 80° C. to 110° C. so that electrodes 5 being a first electrode which are electrically connected to the metal layers 4 are formed.

Subsequently, as shown in FIG. 1E, an insulating material with adhesiveness is coated in a manner to cover the electrodes 5, and an insulating film 6 is formed. This insulating material has a characteristic that it is solid and does not exhibit adhesiveness at the room temperature, exhibits adhesiveness at and above a second temperature higher than this, and is cured at and above a fourth temperature higher than this. Here, for example, the second temperature is approximately 110° C., and the fourth temperature is approximately 130° C. In the present embodiment, used as the insulating material are an epoxy resin based film adhesive and a so-called B-stage adhesive which is liquid but solidified by temporary curing (for example, brand name ABLEFLEX 6200).

As the film adhesive, there is used one whose composition is an adhesive component (epoxy resin and phenol resin, cure promoter) 20 wt %, an inorganic filler (silica or alumina filler of average particle size 1.5 μm, maximum particle size 10 μm) 50 wt %, and a solvent (ether or ketone) 25 wt %. To this film adhesive, a plasticizer can be added in order to maintain a shape after film formation. As this plasticizer, it is the best to use polymethyl methacrylate or polyester. An amount of the solvent to be added is not limited to the added amount stated in the present embodiment but is controlled according to kinds of the used epoxy resin, phenol resin, and amine, or thickness of the adhesive to be formed.

With regard to the epoxy resin to be used in the present invention, any epoxy resin can be used. However, in order to improve heat resistance of the adhesive, an epoxy resin having at least two or more functional groups in one molecule is preferable. There are provided, as such a epoxy resin, bisphenol A epoxy, bisphenol F epoxy, biphenyl epoxy, bisphenol S epoxy, diphenyl ether epoxy, dicyclopentadiene epoxy, cresol novolac epoxy, DPP novolac epoxy, naphthalene epoxy, and the like.

With regard to the phenol resin used as a curing agent for the film adhesive, any phenol resin can be used. However, in consideration of heat resistance and the environment, novolac phenol having two or more functional groups is preferable. There are provided, as such a phenol resin, phenol novolac, cresol novolac, naphthol novolac, xylylene novolac, dicyclopentadiene novolac, styrenated novolac, allyl novolac, and the like.

As the B-stage adhesive, there is used one whose composition is an adhesive component (epoxy resin and phenol resin or amine and cure promoter) 36 wt %, an inorganic filler (silica or alumina filler of average particle size 1.5 μm, maximum particle size 10 μm) 10 wt %, and a solvent (ether or ketone) 10 wt %.

With regard to the phenol resin or the amine used as the curing agent for the B stage adhesive, one with which curing reaction occurs in two steps is suitable, in order to achieve B staging. For this purpose, one having steric hindrance in a molecule is preferable. As a phenol curing agent, decalin metamorphic phenol novolac or p-hydroxybenz aldehyde phenol novolac is preferable. As the amine, an aromatic amine is preferable. There are diaminodiphenylmethane, diaminodiphenylsulphone, and m-phenylenediamine. There are also less toxic ones in which an alkyl group is introduced to individual aromatic amines. As other amines, there are dicyandiamide and the like.

Examples of the conductive material and the insulating material used in the present embodiment are stated in Table 1.

TABLE 1
First Embodiment

| | | Temperature at |
|---|---|---|
| | Temperature at | Which Adhesive |
| | Which | Intensity is |
| | Adhesiveness is | Exhibited by |
| Material | Exhibited | Curing Reaction |
| Conductive | 80° C. (First | 130° C. (Third |
| Material | Temperature) | Temperature) |
| (EN4072 of | | |
| Hitachi Chemical) | | |
| Insulating | 110° C. (Second | 130° C. (Fourth |
| Material | Temperature) | Temperature) |
| (ABLEFLEX 6200) | | |

Subsequently, as shown in FIG. 1F, planarization processing is carried out by performing cutting with a hard cutting tool made of diamond and the like so that surfaces of the electrodes 5 and a surface of the insulating film 6 of the semiconductor chip 1a become continuously planar. According to such surface planarization processing, with surface planarization, heights of respective electrodes 5 become even.

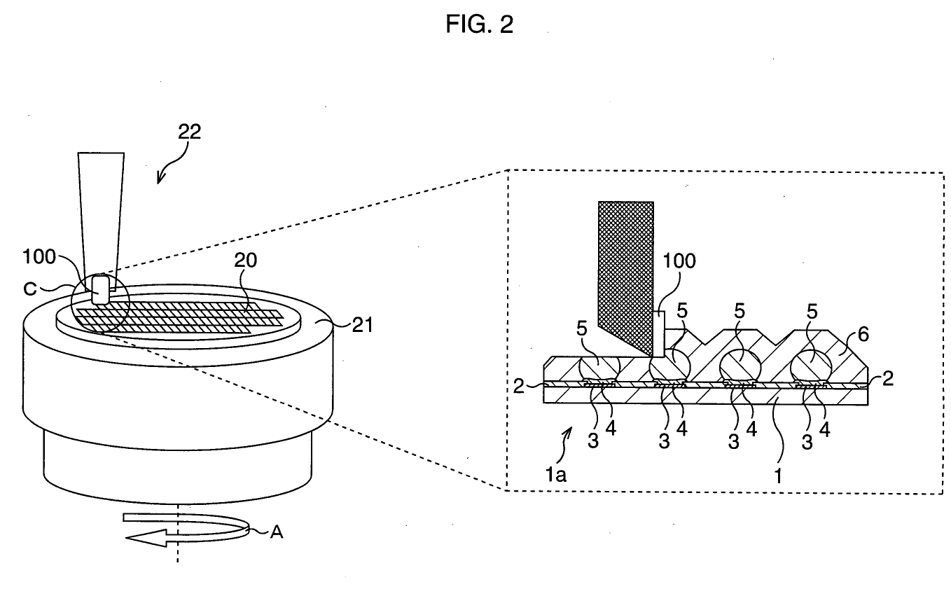

An example of a cutting apparatus is shown in FIG. 2. In the present invention, as shown in the drawing, a case that the cutting is performed on substrate surfaces all together in a state of a semiconductor wafer where a plurality of semiconductor chips 1a are formed before being cut out into individual semiconductor chips 1a. Incidentally, in this case, it is also possible that the individual semiconductor chips 1a are cut out from the semiconductor wafer in a state that the insulating film 6 covering the electrodes 5 is formed as in FIG. 1E, and then the cutting is performed on the diced semiconductor chips 1a by this cutting apparatus.

This cutting apparatus is a so-called ultra-precision lathe. This cutting apparatus includes a substrate supporting table (rotary table) 21 on which semiconductor wafer 20 (or diced semiconductor chip 1a) is placed and fixed by for example vacuum suction and which rotatively drives the semiconductor wafer 20 in a direction of for example an arrow A in the drawing at a predetermined speed (for example, number of rotations being approximately 800 rpm to 1600 rpm), and a hard cutting tool 100 being a tool for cutting made of diamond and the like. Additionally, the cutting apparatus includes a cutting part 22 which drives the cutting tool 100 in a direction from a circumference of the semiconductor wafer 20 toward a rotation center. At a time of the cutting, the cutting tool 100 is abutted on a surface of the semiconductor wafer 20, with the semiconductor wafer 20 being rotated in the arrow direction A, the cutting tool 100 is moved from the circumference of the semiconductor wafer 20 toward the rotation center and then the cutting is performed. Here, on a right side of FIG. 2, there is shown, by enlarging a circle C, a state of the cutting in a step of FIG. 1E. Incidentally, an enlarged view in FIG. 2 is the drawing in which the cutting part 22 is seen from an observer's left side.

Here, the cutting with the ultra-precision lathe is exemplified, but it is a matter of course that cutting can be performed by using a milling machine.

In this cutting step, in the present embodiment, the cutting is performed while the electrodes 5 and the insulating film 6 are kept in solid state without being softened throughout the entire cutting step. More specifically, a temperature of the semiconductor chip 1a is set to be lower than 80° C. which is a lower value of softening (semi-curing) temperatures for the electrodes 5 and the insulating film 6, i.e. the first temperature and the second temperature, to be approximately 50° C. for example. Then, while temperatures to which the electrodes 5 and the insulating film 6 are raised by friction heat generated in the cutting with the cutting tool 100 are controlled under 80° C., the planarization processing is carried out with a temperature range of under 80° C. being kept throughout the entire cutting step.

Subsequently, the individual semiconductor chips 1a are cut out from the semiconductor wafer 20. This step is unnecessary, as a matter of course, if the individual semiconductor chips 1a are cut out before the cutting step as described above. Then, as shown in FIG. 1G, the semiconductor chip 1a and a circuit board 8 on a surface of which electrodes 7 being second electrodes are formed are aligned in a manner that the electrodes 5 of the semiconductor chip 1a face the electrodes 7 of the circuit board 8. Next, with temperatures of semiconductor chip 1a and the circuit board 8 being higher than 110° C. which is a higher value of the softening temperatures for the electrode 5 and the insulating film 6, i.e. the first temperature and the second temperature, and at the same time lower than 130° C. which is a lower value of solidifying (curing) temperatures for the electrode 5 and the insulating film 6, i.e. the third temperature and the fourth temperature, the electrodes 5 are corresponded to the electrodes 7. Then, the insulating film 6 is softened so that the insulating resin of the insulating film 6 fills between the electrodes 5 and the electrodes 7, and the electrodes and the electrodes 7 are contacted.

Since the surfaces of the electrodes 5 and the surface of the insulating film 6 are planarization processed by the above-described cutting, the electrodes 5 and the insulating film 6 can be recognized by reflectivities and hues of the respective surfaces, with a predetermined reflectivity measurement apparatus and camera apparatus. It is also possible to utilize differences of the reflectivities and the hues to align the electrodes 5 and the electrodes 7.

In such a state, the semiconductor chip 1a and the circuit board 8 are pressed at and above a higher value of the third temperature and the fourth temperature, for example at 130° C. to 150° C., at a load of several gf per electrode, for example, at 10 gf, for a predetermined time (for example 5 seconds), to cure the conductive material of the electrodes 5 and the insulating material of the insulating film 6. Then the temperature is further kept at 150° C. for approximately 30 minutes so that the conductive material and the insulating material are completely cured. Consequently, the semiconductor chip 1a and the circuit board 8 are connected by the insulating film 6, as well as the electrodes 5 and 7 are joined. At this time, the electrodes 5 and 7 are electrically connected and conducted, as well as the insulating film 6 adheres securely due to excellent adhesiveness thereof so that the semiconductor chip 1a and the circuit board 8 are securely joined.

Incidentally, in this case, it is also possible that the temperature of the semiconductor chip 1a is set to be under 80° C. which is the lower value of the respective softening temperatures for the electrodes 5 and the insulating film 6 and the temperature of the circuit board 8 is set to be higher than 110° C. which is the higher value of the respective softening temperatures for the electrodes 5 and the insulating film 6, and in this state the electrodes 5 and the electrodes 7 are corresponded and contacted, with the temperatures of the electrode 5 and insulating film 6 becoming at and above 110° C. so that the electrodes 5 and insulating film 6 are softened.

Thereafter, on a connecting terminal formed on the other principal surface of the circuit board 8, for example a solder ball and the like for external connection is mounted (both are not shown), and the semiconductor device is completed.

As described above, according to the present embodiment, there can be formed a semiconductor device which is low in cost, has an even and smooth height, enables forming of metal terminals connected at a low load, enables mounting at low damage, and has high reliability.

Also, as described above, the planarization processing by the cutting tool has various merits compared with grinding or polishing. They are briefly described below.

In a case of the grinding, there is used a grinding disk of resin or metal in which (micron level) particles of high-hardness materials such as diamond are filled. The grinding disk is rotated and grinds an object to be ground, with a plane or an edge of the disk.

In such a grinding process, there arise problems that dust of the object to be ground adheres to the resin which is a base material of the grinding disk, causing a surface of the grinding disk to be in a state that the grinding is impossible, or that the base material is contaminated by a metal ion, and so on. There also arises a problem that the dust of the object to be ground is ploughed into a surface of the object to be ground.

Additionally, there can arise another problem that, as grinding is performed with a plane, friction heat raises temperature and the resin being the object to be ground melts. As a result, when an object to be ground with adhesive resin is ground, there arises a phenomenon that the resin melted onto the grinding disk adheres between diamond particles of the grinding disk, making the grinding impossible. Though heat generation by friction can be evaded by sousing water on the surface of the object to be ground and so on, there can arise a problem that the cooling water deteriorates the adhesive resin.

In a case of the polishing, as micron level abrasive grains are used for polishing, there arises a phenomenon that the abrasive grains dig into a surface of an object to be polished (resin surface or bump surface). As adhesive resin, in particular, is low in hardness and soft, many abrasive grains tend to dig and it is difficult to remove the grains which have dug. In order to completely remove them, it is necessary that after the surface of the object to be polished is thinly dissolved (together with abrasive grains) by a chemical method, moisture penetrated in the resin is heat dried.

In particular, if the object to be polished is formed of a conductive adhesive which contains silver (Ag), water and alcohols used in the polishing adversely affect the resin (in particular adhesive resin), in such a way that water for polishing causes oxidation of silver.

Also, there arises a problem that if two or more types of materials with different hardnesses, such as the metal terminal and the insulating resin, a level difference called dishing occurs on a polished surface and a flat surface is not obtained.

As described above, the planarization by the grinding or the polishing is not practical.

If cutting processing with the cutting tool is performed, there is a merit that these problems do not arise, as the plane is not used for the planarization processing. A cut surface after the cutting processing with the cutting tool is clean without adhesion of cutting dust.

Incidentally, in the present embodiment, a case that the above cutting is performed only on one principal surface of the semiconductor chip 1a is exemplified. It is considered sufficient that the cutting is not performed, on one principal surface of the circuit board 8, on which a plurality of electrodes 7 are continuously formed evenly to some extent. However, the one principal surface can also be planarized by the cutting as in the semiconductor chip 1a. In this case, it is possible to perform the cutting in a state that only the plural electrodes 7 are formed on the one principal surface (in a state that the insulating film to cover the electrodes 7 does not exist).

### Second Embodiment

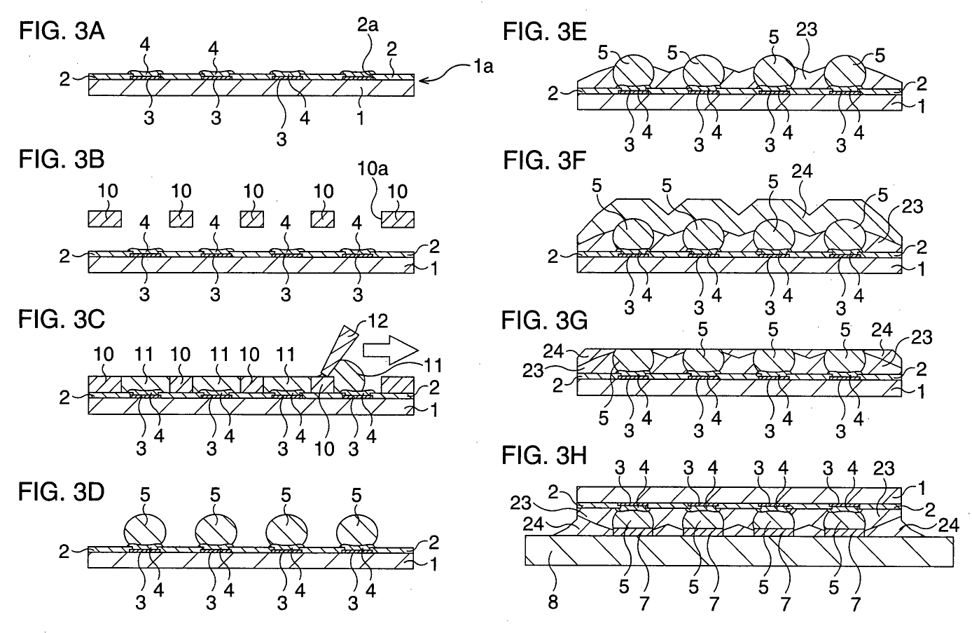

FIG. 3 is a schematic sectional view showing a method for manufacturing a semiconductor device according to a second embodiment step by step. For description convenience, wordings such as “second temperature” are used in descriptions below, but they are unrelated to the “second temperature” and the like in the above first embodiment.

Here, a first base is a semiconductor chip which is diced from a semiconductor wafer and on a principal surface of which electrode terminals are disposed, and a second base is a circuit board on which the semiconductor chip is to be flip-chip mounted. Now, a case that the semiconductor chip is mounted on the circuit board is described. The circuit board includes an insulating substrate formed of glass epoxy and the like, and a conductive layer formed on the surface and/or inside thereof. On its mounting surface for the semiconductor chip, there is disposed electrode terminals corresponding to the electrode terminals of the semiconductor chip to be mounted.

In the present embodiment, after a surface, i.e., a mounted surface, of the semiconductor chip is planarized by cutting, the electrode terminals of the semiconductor chip and the electrode terminals of the circuit board are faced and connected.

In FIG. 3A, a semiconductor chip 1a includes, on one principal surface thereof, a semiconductor substrate 1 made of silicon (Si) on which a logic circuit and/or a storage circuit and the like (not shown) constituted with a functional element such as an MOS transistor and a passive element such as a capacitor element are/is formed, an insulating layer 2 made of silicon oxide and the like which is disposed to cover the one principal surface of the semiconductor substrate 1, openings 2a selectively disposed in the insulating layer 2, and electrode layers disposed in the opening 2a parts.

This electrode layer includes a foundation metal layer composed of a multi-layered body of a metal layer 3 disposed on an aluminum (Al) electrode pad (not shown) lead out from the functional element part and/or the passive element part and a metal layer 4 disposed on the metal layer 3. Nickel (Ni) and gold (Au) are formed by being sequentially deposited by an electroless plating method. As a material of the metal layer 3, there is used a metal-such as aluminum (Al), copper (Cu), gold (Au), silver (Ag), nickel (Ni) or tungsten (W), or an alloy of these. As a material of the metal layer 4, there is used a metal such as gold (Au), tin (Sn), copper (Cu), silver (Ag), nickel (Ni), or tungsten (W), or an alloy of these.

Subsequently, as shown in FIG. 3B, a metal mask 10 is aligned and formed in a manner that openings 10a thereof reveals surfaces of the respective metal layers 4.

Subsequently, as shown in FIG. 3C, an Ag paste 11 (for example, brand name EN4072 of Hitachi Chemical Co., Ltd.) is used as a conductive material, and the Ag paste 11 is stamped by a printing method with a squeezee 12 to fill inside the openings 10a of the metal mask 10. This Ag paste 11 has a characteristic that after semi-cured it is solid and does not exhibit adhesiveness at a room temperature, exhibits adhesiveness at and above a first temperature higher than this, and is cured at and above a sixth temperature higher than this. Here, for example, the first temperature is approximately 80° C., and the sixth temperature is approximately 130° C. Incidentally, as the conductive material in the present embodiment, in addition to the Ag paste, an Au paste, a Pd paste, a Pt paste, or an alloy paste of these can be used.

Subsequently, as shown in FIG. 3D, with the metal mask 10 being removed, the Ag paste 11 is semi-cured (so-called B-stage cured) at a temperature of 80° C. to 110° C. so that electrodes 5 being first electrodes which are electrically connected to the metal layers 4 are formed.

Subsequently, with two kinds of insulating materials which have adhesiveness (a first and a second insulating material), insulating films are formed in a manner to cover the electrodes 5.

More specifically, first, as shown in FIG. 3E, in the semiconductor chip 1a, the first insulating material is filled between the electrodes 5 in a manner to be lower than heights of the electrodes 5 so that a first insulating film 23 is formed. Subsequently, as shown in FIG. 3F, the second insulating material is deposited on the first insulating film 23 in a manner to cover the electrodes 5 so that a second insulating film 24 is formed.

Here, the first insulating material has a characteristic that it is solid and does not exhibit adhesiveness at a room temperature, exhibits adhesiveness at and above a second temperature higher than this, and is cured at and above a fourth temperature higher than this. Here, for example, the second temperature is approximately 110° C., and the fourth temperature is approximately 130° C. The second insulating material has a characteristic that it is solid and does not exhibit adhesiveness at the room temperature, exhibits adhesiveness at and above a third temperature higher than this, and is cured at and above a fifth temperature higher than this. Here, for example, the third temperature is approximately 100° C., and the fifth temperature is approximately 150° C. Further, the first insulating material is the material that exhibits strong adhesive intensity with the semiconductor chip 1a at and above the fourth temperature. The second insulating material is the material that exhibits strong adhesive intensity with both the first insulating material and the circuit board 8 at and above the fifth temperature. In the present embodiment, used as the first insulating material are the epoxy resin based film adhesive and the B-stage adhesive described in the first embodiment. As the second insulating material the one with brand name UF-536 of Hitachi Chemical Co., Ltd. is used.

Examples of the conductive material and the insulating materials used in the present embodiment are stated in Table 2.

TABLE 2
Second Embodiment

| | | Temperature at |
|---|---|---|
| | Temperature at | Which Adhesive |
| | Which | Intensity is |
| | Adhesiveness is | Exhibited by |
| Material | Exhibited | Curing Reaction |
| Conductive | 80° C. (First | 130° C. (Sixth |
| Material | Temperature) | Temperature) |
| (EN4072 of | | |
| Hitachi Chemical) | | |
| First Insulating | 110° C. (Second | 130° C. (Fourth |
| Material | Temperature) | Temperature) |
| (ABLEFLEX 6200) | | |
| Second Insulating | 100° C. (Third | 150° C. (Fifth |
| Material | Temperature) | Temperature) |
| (UF-536 of | | |
| Hitachi Chemical) | | |

Subsequently, as shown in FIG. 3G, with the cutting apparatus shown in FIG. 2 being used, planarization processing is carried out by performing cutting with a hard cutting tool made of diamond and the like so that surfaces of the electrodes 5 and a surface of the second insulating film 24 of the semiconductor chip 1a become continuously planar. According to such surface planarization processing, planar surfaces of the electrodes 5 and the second insulating film 24 appear from cut surfaces. Note, however, that when the second insulating film 24 is formed, some amount of the first insulating material may be coated on the electrodes 5. In this case, on the cut surfaces after the cutting, the thin first insulating material appears in a manner to cover peripheries of the electrodes 5. This first insulating material is extremely small in amount compared with the appearing second insulating material, and does not influence adhesiveness. Meanwhile, heights of respective electrodes 5 become even as the surfaces are planarized.

In this cutting step, in the present embodiment, the cutting is performed while the electrodes 5, the first insulating film 23, and the second insulating film 24 are kept in solid state without being softened throughout the entire cutting step. More specifically, a temperature of the semiconductor chip 1a is set to be lower than 80° C. which is a lowest value of softening (semi-curing) temperatures for the electrodes 5, the first insulating film 23, and the second insulating film 24, i.e. the first temperature, the second temperature, and the third temperature, to be approximately 50° C. for example. Then, while temperatures to which the electrode 5, the first insulating film 23, and the second insulating film 24 are raised by friction heat generated in the cutting while the cutting tool 100 are controlled under 80° C., the planarization processing is carried out, with a temperature range of under 80° C. being kept throughout the entire cutting step.

Subsequently, the individual semiconductor chips 1a are cut out from a semiconductor wafer 20. This step is unnecessary, as a matter of course, if the individual semiconductor chips 1a are cut out before the cutting step. Then, as shown in FIG. 3H, the semiconductor chip 1a and a circuit board 8 on a surface of which electrodes 7 being second electrodes are formed are aligned in a manner that the electrodes 5 of the semiconductor chip 1a face the electrodes 7 of the circuit board 8. Next, with temperatures of semiconductor chip 1a and the circuit board 8 being higher than 110° C. which is a highest value of the softening temperatures for the electrodes 5, the first insulating film 23, and the second insulating film 24, i.e. the first temperature, the second temperature, and the third temperature, and at the same time lower than 130° C. which is a lowest value of solidifying (curing) temperatures for the electrodes 5, the first insulating film 23, and the second insulating film 24, i.e. the fourth temperature, the fifth temperature, and the sixth temperature, the electrodes 5 are corresponded to the electrodes 7. Then, the first insulating film 23 and the second insulating film 24 are softened so that the second insulating resin of the second insulating film 24 fills between the electrodes 5 and the electrodes 7, and the electrodes 5 and the electrodes 7 are contacted.

Here, after surfaces of the electrodes 5 and a surface of the second insulating film 24 are planarization processed by the above cutting, the electrodes 5 and the second insulating film 24 can be recognized by reflectivities and hues of the respective surfaces, with a predetermined reflectivity measurement apparatus and camera apparatus. It is also possible to utilize differences of the reflectivities and the hues to align the electrodes 5 and the electrodes 7.

In such a state, the semiconductor chip 1a and the circuit board 8 are pressed at and above 150° C. being a highest value of the fourth temperature, the fifth temperature, and the sixth temperature, for example at 150° C., at a load of several gf per electrode, for example, at 10 gf, for a predetermined time (for example 5 seconds), to cure the conductive material of the electrodes 5 and the respective insulating materials of the first insulating film 23 and the second insulating film 24. Then the temperature is further kept at 150° C. for approximately 30 minutes so that the conductive material and the respective insulating materials are completely cured. Consequently, the semiconductor chip 1a and the circuit board 8 are connected by the second insulating film 24, and the electrodes 5 and 7 are joined. At this time, the electrodes 5 and 7 are electrically connected and conducted, as well as the second insulating film 24 adheres securely due to excellent adhesiveness thereof so that the semiconductor chip 1a and the circuit board 8 are securely joined. Here, since the second insulating material excels at adhesiveness to the first insulating material and the circuit board 8, the semiconductor chip 1a and the circuit board 8 are joined more securely.

Incidentally, in this case, it is also possible that the temperature of the semiconductor chip 1a is set to be lower than 80° C. which is the lowest value of the respective softening temperatures for the electrodes 5, the first insulating film 23, and the second insulating film 24, and the temperature of the circuit board 8 is set to be higher than 110° C. which is the highest value of the respective softening temperatures for the electrodes 5, the first insulating film 23, and the second insulating film 24, and in this state the electrodes 5 and the electrodes 7 are corresponded and contacted, with the temperatures of the electrodes 5 and insulating film 6 becoming at and above 110° C. so that the electrodes 5, the first insulating film 23, and the second insulating film 24 are softened.

Thereafter, on a connecting terminal formed on the other principal surface of the circuit board 8, for example a solder ball and the like for external connection is mounted (both are not shown), and the semiconductor device is completed.

As described above, according to the present embodiment, there can be formed a semiconductor device which is low in cost, has an even and smooth height, enables forming of metal terminals connected at a low load, enables mounting at low damage, and has high reliability. Further, by using two kinds of insulating materials (the first and the second insulating materials), the semiconductor chip 1a and the circuit board 8 can be joined more securely. Also, it is possible to choose a material having strong adhesiveness to the semiconductor chip 1a as the first insulating material, so that a range of choices for the material is expanded.

Incidentally, in the present embodiment, a case that the above cutting is performed only on one principal surface of the semiconductor chip 1a is exemplified. It is considered sufficient that the cutting is not performed on one principal surface of the circuit board 8, on which a plurality of electrodes 7 are continuously formed evenly to some extent. However, the one principal surface can also be planarized by the cutting as in the semiconductor chip 1a. In this case, it is possible to perform the cutting in a state that only the plural electrodes 7 are formed on the one principal surface (in a state that the insulating film to cover the electrodes 7 does not exist).

### Third Embodiment

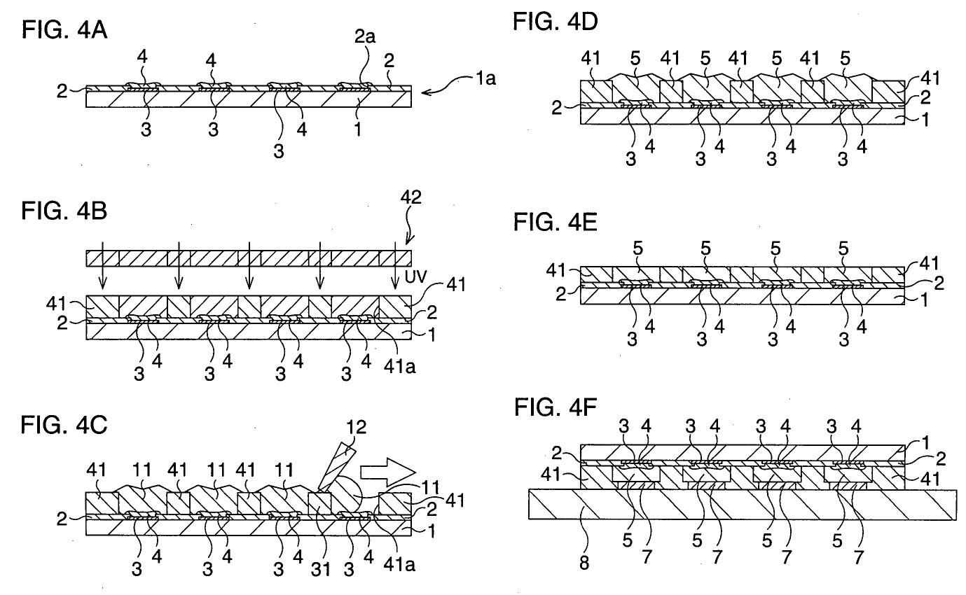

FIG. 4 is a schematic sectional view showing a method for manufacturing a semiconductor device according to a third embodiment step by step. For description convenience, wordings such as “second temperature” are used in descriptions below, but they are unrelated to the “second temperature” and the like in the first and the second embodiments described above.

Here, a first base is a semiconductor chip which is diced from a semiconductor wafer and on a principal surface of which electrode terminals are disposed, and a second base is a circuit board on which the semiconductor chip is to be flip-chip mounted. Now, a case that the semiconductor chip is mounted on the circuit board is described. The circuit board includes an insulating substrate formed of glass epoxy and the like, and a conductive layer formed on the surface and/or inside thereof. On its mounting surface for the semiconductor chip, there are disposed electrode terminals corresponding to the electrode terminals of the semiconductor chip to be mounted.

In the present embodiment, after a surface, i.e., a mounted surface, of the semiconductor chip is planarized by cutting, the electrode terminals of the semiconductor chip and the electrode terminals of the circuit board are faced and connected.

In FIG. 4A, a semiconductor chip 1a includes, on one principal surface thereof, a semiconductor substrate 1 made of silicon (Si) on which a logic circuit and/or a storage circuit and the like (not shown) constituted with a functional element such as an MOS transistor and a passive element such as a capacitor element are/is formed, an insulating layer 2 made of silicon oxide and the like which is disposed to cover the one principal surface of the semiconductor substrate 1, openings 2a selectively disposed in the insulating layer 2, and electrode layers disposed in the opening 2a parts.

This electrode layer includes a foundation metal layer composed of a multi-layered body of a metal layer 3 disposed on an aluminum (Al) electrode pad (not shown) lead out from the functional element part and/or the passive element part, and a metal layer 4 disposed on the metal layer 3. Nickel (Ni) and gold (Au) are formed by being sequentially deposited by an electroless plating method. As a material of the metal layer 3, there is used a metal such as aluminum (Al), copper (Cu), gold (Au), silver (Ag), nickel (Ni) or tungsten (W), or an alloy of these. As a material of the metal layer 4, there is used a metal such as gold (Au), tin (Sn), copper (Cu), silver (Ag), nickel (Ni), or tungsten (W), or an alloy of these.

Subsequently, as shown in FIG. 4B, an insulating film 41 is formed on a surface of the semiconductor chip 1a with an insulating material which is a photosensitive insulating adhesive (for example, brand name WPR-C200 of JSR). Then, by photolithography with a photomask 42, the insulating film 41 is exposed to ultraviolet ray and developed. By this photolithography, openings 41a to reveal surfaces of the respective metal layers 4 are formed in the insulating film 41. This insulating material has a characteristic that it is solid and does not exhibit adhesiveness at a room temperature, exhibits adhesiveness at and above a second temperature higher than this, and is cured at and above a fourth temperature higher than this. After being cured at and above the fourth temperature, the insulating material is kept cured even at the room temperature. Here, for example, the second temperature is approximately 110° C., and the fourth temperature is approximately 190° C.

Subsequently, as shown in FIG. 4C, an Ag paste 11 (for example, brand name EN4072 of Hitachi Chemical Co., Ltd.) is used as a conductive material, and the Ag paste 11 is stamped by a printing method with a squeezee 12 to fill inside the openings 41a of the insulating film 41. This Ag paste 11 has a characteristic that after semi-cured it is solid and does not exhibit adhesiveness at a room temperature, exhibits adhesiveness at and above a first temperature higher than this, and is cured at and above a third temperature higher than this. Here, for example, the first temperature is approximately 80° C., and the third temperature is approximately 130° C. Incidentally, as the conductive material used here, in addition to the Ag paste, an Au paste, a Pd paste, a Pt paste, or an alloy paste of these can be used.

Examples of the conductive material and the insulating material used in the present embodiment are stated in Table 3.

TABLE 3
Third Embodiment

| | | Temperature at |
|---|---|---|
| | Temperature at | Which Adhesive |
| | Which | Intensity is |
| | Adhesiveness is | Exhibited by |
| Material | Exhibited | Curing Reaction |
| Conductive Material | 80° C. (First | 130° C. (Third |
| (Hitachi Chemical | Temperature) | Temperature) |
| EN4072) | | |
| Photosensitive | 110° C. (Second | 190° C. (Fourth |
| Insulating Material | Temperature) | Temperature) |
| (JSR WPR-C200) | | |

Subsequently, as shown in FIG. 4D, the Ag paste 11 is semi-cured (so-called B-stage cured) at a temperature of 80° C. to 110° C. so that electrodes 5 being first electrodes which are electrically connected to the metal layers 4 inside the openings 41a of the insulating film 41 are formed.

Subsequently, as shown in FIG. 4E, with the cutting apparatus of FIG. 2 being used, planarization processing is carried out by performing cutting with a hard cutting tool made of diamond and the like so that surfaces of the electrodes 5 and a surface of the insulating film 41 of the semiconductor chip 1a become continuously planar. At this time, with surface planarization, heights of respective electrodes 5 become even.

In this cutting step, in the present embodiment, the cutting is performed while the electrodes 5 and the insulating film 41 are kept in solid state without being softened throughout the entire cutting step. More specifically, a temperature of the semiconductor chip 1a is set to be lower than 80° C. which is a lower value of softening (semi-curing) temperatures for the electrodes 5 and the insulating film 41, i.e. the first temperature and the second temperature, to be approximately 50° C. for example. Then, while temperatures to which the electrodes 5 and the insulating film 41 are raised by friction heat generated in the cutting with the cutting tool 100 are controlled under 80° C., the planarization processing is carried out, with a temperature range of under 80° C. being kept throughout the entire cutting step.

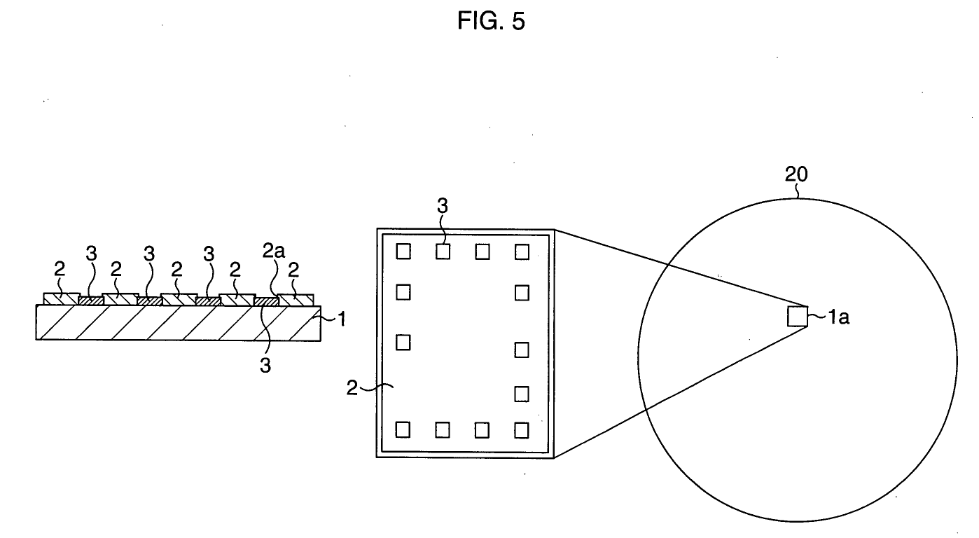

Subsequently, the individual semiconductor chips 1a are cut out from a semiconductor wafer 20. This step is unnecessary, as a matter of course, if the individual semiconductor chips 1a are cut out before the cutting step. Then, as shown in FIG. 5F, the semiconductor chip 1a and a circuit board 8 on a surface of which electrodes 7 being second electrodes are formed are aligned in a manner that the electrodes 5 of the semiconductor chip 1a face the electrodes 7 of the circuit board 8. Next, with temperatures of semiconductor chip 1a and the circuit board 8 being higher than 110° C. which is a higher value of the softening temperatures for the electrodes 5 and the insulating film 41, i.e. the first temperature and the second temperature, and at the same time lower than 130° C. which is a lower value of solidifying (curing) temperatures for the electrodes 5 and the insulating film 41, i.e. the third temperature and the fourth temperature, the electrodes 5 are corresponded to the electrodes 7. Then, the insulating film 41 is softened so that insulating resin of the insulating film 41 fills between the electrodes 5 and the electrodes 7, and the electrodes 5 and the electrodes 7 are contacted.

Here, after surfaces of the electrodes 5 and a surface of the insulating film 41 are planarization processed by the above cutting, the electrodes 5 and the insulating film 41 can be recognized by reflectivities and hues of the respective surfaces with a predetermined reflectivity measurement apparatus and camera apparatus. It is also possible to utilize differences of the reflectivities and the hues to align the electrodes 5 and the electrodes 7.

In such a state, the semiconductor chip 1a and the circuit board 8 are pressed at and above a higher value of the third temperature and the fourth temperature, for example at 190° C., at a load of several gf per electrode, for example, at 10 gf, for a predetermined time (for example 5 seconds), to cure the conductive material of the electrodes 5 and the insulating material of the insulating film 41. Then the temperature is further kept at 190° C. for approximately 30 minutes so that the conductive material and the insulating material are completely cured. Consequently, the semiconductor chip 1a and the circuit board 8 are connected by the insulating film 41, and the electrodes 5 and 7 are joined. At this time, the electrodes 5 and 7 are electrically connected and conducted, as well as the insulating film 41 adheres securely due to its excellent adhesiveness so that the semiconductor chip 1a and the circuit board 8 are securely joined.

Incidentally, in this case, it is possible that the temperature of the semiconductor chip 1a is set to be lower than 80° C. which is the lower value of the respective softening temperatures for the electrode 5 and the insulating film 41 and the temperature of the circuit board 8 is set to be higher than 110° C. which is the higher value of the respective softening temperatures for the electrodes 5 and the insulating film 41, and in this state the electrodes 5 and the electrodes 7 are corresponded and contacted, with the temperature of the electrodes 5 and insulating film 41 becoming at and above 110° C. so that the electrodes 5 and the insulating film 41 are softened.

Thereafter, on a connecting terminal formed on the other principal surface of the circuit board 8, for example a solder ball and the like for external connection is mounted (both are not shown), and the semiconductor device is completed.

As described above, according to the present embodiment, there can be obtained a semiconductor device which is low in cost, has an even and smooth height, enables forming of metal terminals connected at a low load, enables mounting at low damage, and has high reliability. Additionally, the insulating film 41 functions as the mask for forming the electrodes 5 by the printing method and also as the insulating adhesive in bonding and fixing the semiconductor chip 1a and the circuit board 8. Therefore, the number of manufacturing processes is reduced, and the semiconductor device can be manufactured easily.

Incidentally, in the present embodiment, a case that the above cutting is performed only on one principal surface of the semiconductor chip 1a is exemplified. It is considered sufficient that the cutting is not performed on one principal surface of the circuit board 8, on which a plurality of electrodes 7 are continuously formed evenly to some extent. However, the one principal surface can also be planarized by the cutting as in the semiconductor chip 1a. In this case, it is possible to perform the cutting in a state that only the plural electrodes 7 are formed on the one principal surface (in a state that the insulating film to cover the electrodes 7 does not exist).

### Fourth Embodiment

In the present embodiment, a case that the present invention is applied to forming of an RFID is exemplified. The RFID is an abbreviation of Radio Frequency Identification, which is a technology to realize recognition and management of a person or a thing by recording data in a wireless chip (RFID tag) of a size of approximately several mm to several cm and by reading/writing contents of the data with an apparatus via a radio wave and the like. Incidentally, the present invention can also be applied to forming of a non-contact IC such as Smart Card.

For description convenience, wordings such as “second temperature” are used in descriptions below, but they are unrelated to the “second temperature” and the like in the first to the third embodiments described above.

FIG. 5 to FIG. 14 are schematic views showing a method for manufacturing an RFID according to a fourth embodiment step by step.

Here, there is exemplified a case where a first base is a semiconductor chip which is diced from a semiconductor wafer and on a principal surface of which electrode terminals are disposed, and a second base is an RFID antenna part where an antenna is formed on a substrate made of a material such as a polyethylene terephthalate resin (PET resin). In the present embodiment, after a surface, i.e., a mounted surface, of the semiconductor chip is planarized by cutting, the electrode terminals of the semiconductor chip and antenna terminals of the RFID antenna part are faced and connected.

In FIG. 5, a semiconductor chip 1a includes, on one principal surface thereof, a semiconductor substrate 1 made of silicon (Si) on which a logic circuit and/or a storage circuit and the like (not shown) constituted with a functional element such as an MOS transistor and a passive element such as a capacitor element are/is formed, an insulating layer 2 made of silicon oxide and the like which is disposed to cover the one principal surface of the semiconductor substrate 1, openings 2a selectively disposed in the insulating layer 2, and metal layers 3 disposed in the opening 2a parts. As a material of the metal layer 3, there is used a metal such as aluminum (Al), copper (Cu), gold (Au), silver (Ag), nickel (Ni) or tungsten (W), or an alloy of these.

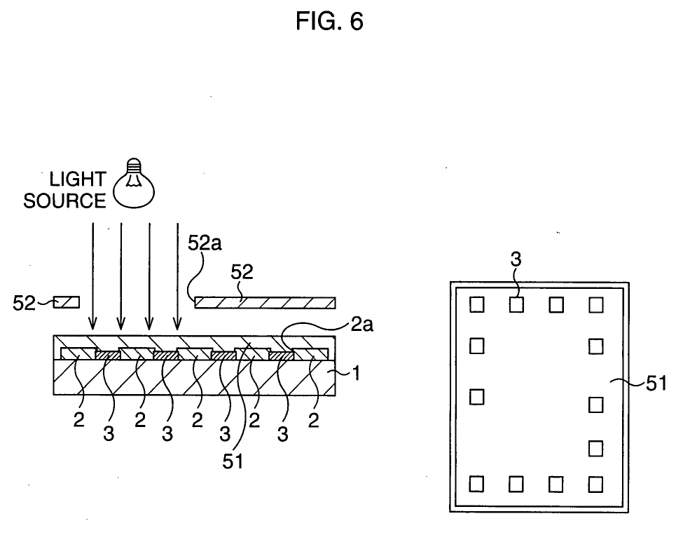

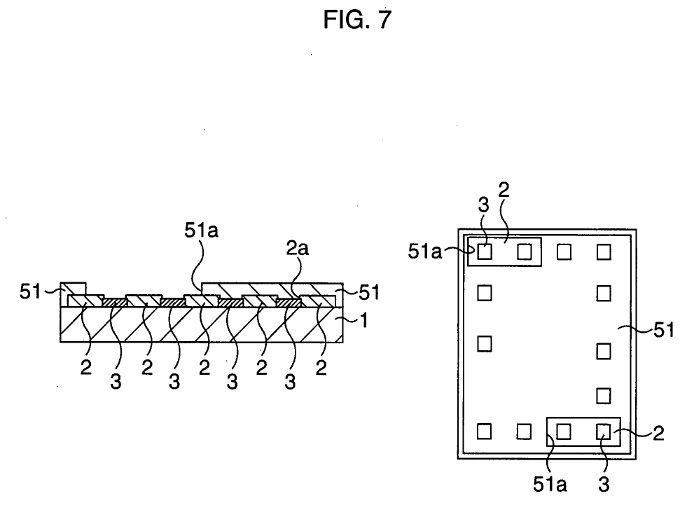

Subsequently, as shown in FIG. 6, a photosensitive resin 51 such as polyimide is coated on an entire surface of the semiconductor chip 1a in a manner to cover the metal layers 3. With a photomask 52 having an opening 52a formed only on a portion corresponding to above predetermined metal layers 3 among a plurality of metal layers 3 being used, the portion corresponding to above the predetermined metal layer 3 is exposed. By developing the photosensitive resin 51, as shown in FIG. 7, an opening 51a which reveals only above the predetermined metal layers 3 is formed on the photosensitive resin 51. In an example of the drawing, the openings 51a are formed in two positions on the surface of the semiconductor chip 1a in a manner that above adjacent two metal layers 3 are respectively opened.

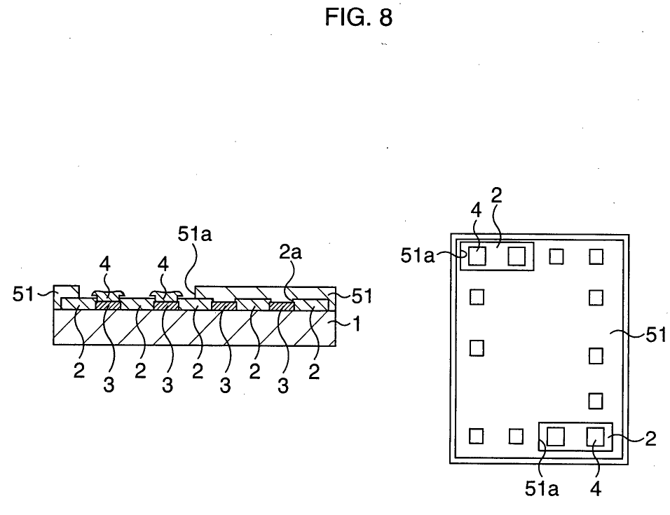

Subsequently, after the photosensitive resin 51 is cured, as shown in FIG. 8, nickel (Ni) and gold (Au) are sequentially deposited by an electroless plating method for example, so that metal layers 4 are formed on the metal layers 3 appearing from the opening 51a.

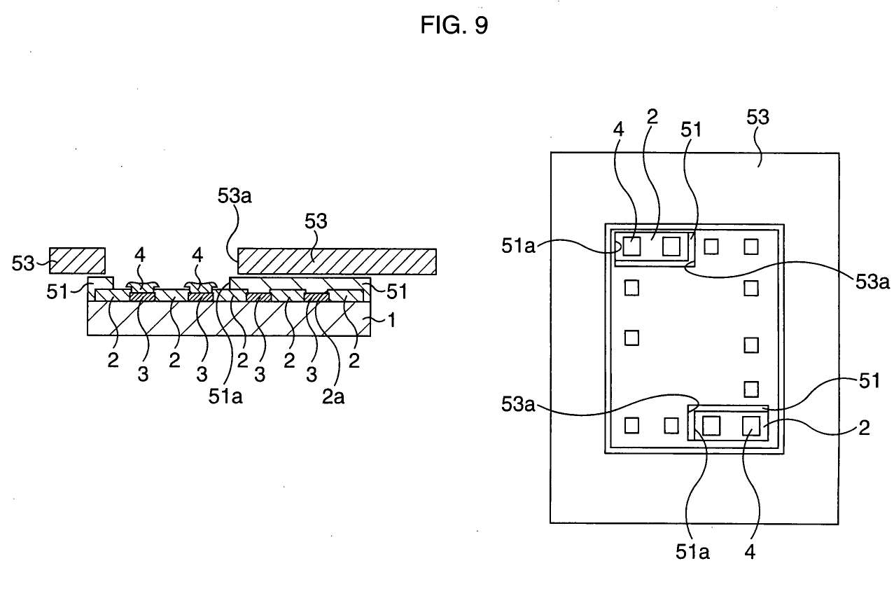

Subsequently, as shown in FIG. 9, a metal mask 53 is set above the photosensitive resin 51. This metal mask 53 has, formed on a portion corresponding to the opening 51a of the photosensitive resin 51, an opening 53a which is larger than the opening 51a. The metal mask 53 is aligned to the opening 51a in a manner that the metal layers 4 appear inside the opening 53a.

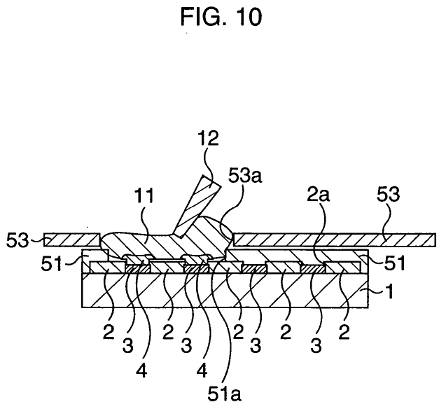

Subsequently, as shown in FIG. 10, an Ag paste 11 (for example, brand name EN4072 of Hitachi Chemical Co., Ltd.) is used as a conductive material, and the Ag paste 11 is stamped by a printing method with a squeezee 12 to fill inside the opening 53a of the metal mask 53. This Ag paste 11 has a characteristic that after semi-cured it is solid and does not exhibit adhesiveness at a room temperature, exhibits adhesiveness at and above a first temperature higher than this, and is cured at and above a third temperature higher than this. Here, the first temperature is approximately 80° C., and the third temperature is approximately 130° C. Incidentally, as the conductive material in the present embodiment, in addition to the Ag paste, an Au paste, a Pd paste, a Pt paste, or the like can be used.

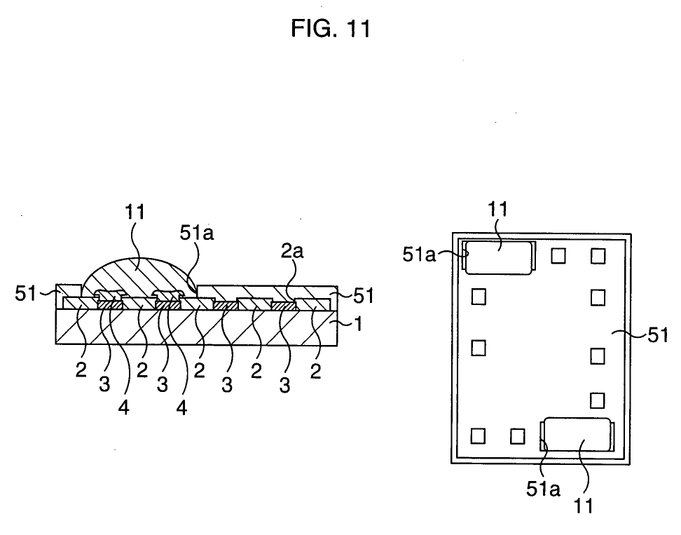

Subsequently, as shown in FIG. 11, with the metal mask 53 being removed, the Ag paste 11 is semi-cured (so-called B-stage cured) at a temperature of 80° C. to 110° C. so that electrodes 5 being first electrodes which are electrically connected to the metal layers 4 inside the opening 51a of the photosensitive resin 51 are formed.

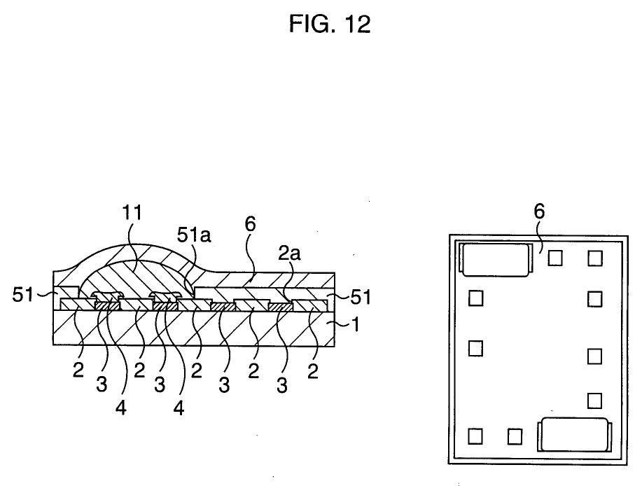

Subsequently, as shown in FIG. 12, with an insulating material having adhesiveness being used, an insulating film 6 is formed in a manner to cover the electrodes 5. This insulating material has a characteristic that it is solid and does not exhibit adhesiveness at the room temperature, exhibits adhesiveness at and above a second temperature higher than this, and is cured at and above a fourth temperature higher than this. After being cured at and above the fourth temperature, the insulating material is kept cured even at the room temperature. Here, the second temperature is approximately 110° C., and the fourth temperature is approximately 130° C. In the present embodiment, used as the insulating materials are an epoxy resin based film adhesive and a B-stage adhesive, as in the first embodiment. Additionally, the insulating material of the insulating film 6 is opaque to visible light.

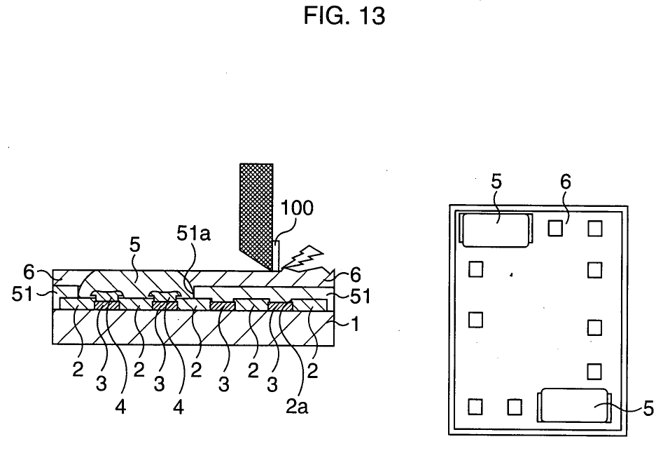

Subsequently, as shown in FIG. 13, with a cutting apparatus similarly structured to that of FIG. 2 being used, planarization processing is carried out by performing cutting with a hard cutting tool made of diamond and the like so that surfaces of the electrodes 5 and a surface of the insulating film 6 of the semiconductor chip 1a become continuously planar. With this surface planarization, heights of respective electrodes 5 become even.

In this cutting step, in the present embodiment, cutting is performed while the electrodes 5 and the insulating film 6 are kept in solid state without being softened throughout the entire cutting step. More specifically, a temperature of the semiconductor chip 1a is set to be lower than 80° C. (for example 50° C.) which is a lower value of softening (semi-curing) temperatures for the electrodes 5 and the insulating film 6, i.e. the first temperature and the second temperature. Then, while temperatures to which the electrodes 5 and the insulating film 6 are raised by friction heat generated in the cutting with the cutting tool 100 are controlled under 80° C., the planarization processing is carried out, with a temperature range of under 80° C. being kept throughout the entire cutting step.

According to such surface planarization processing, cut surfaces of the electrodes 5 surrounded by the insulating film 6 appear from the surface of the semiconductor chip 1a. At this time, the electrodes 5 and the insulating film 6 can be relatively recognized by differences of reflectivities and hues of the respective surfaces with a predetermined reflectivity measurement apparatus and camera apparatus. Therefore, an opaque material can be used as the insulating material of the insulating film 6 as described above. Since the insulating film 6 is opaque, inside of the insulating film 6 can not be seen from the surface of the planarized semiconductor chip 1a. Therefore, there can be prevented unauthorized alteration of stored data and the like such as changing of ROM contents.

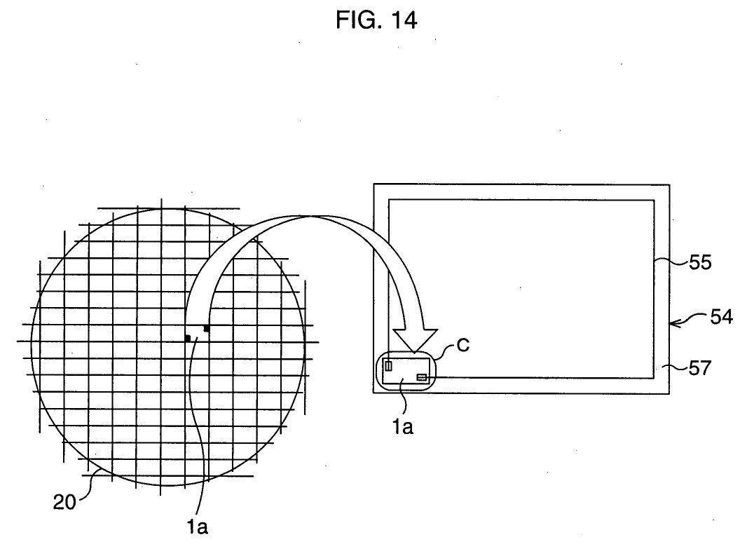

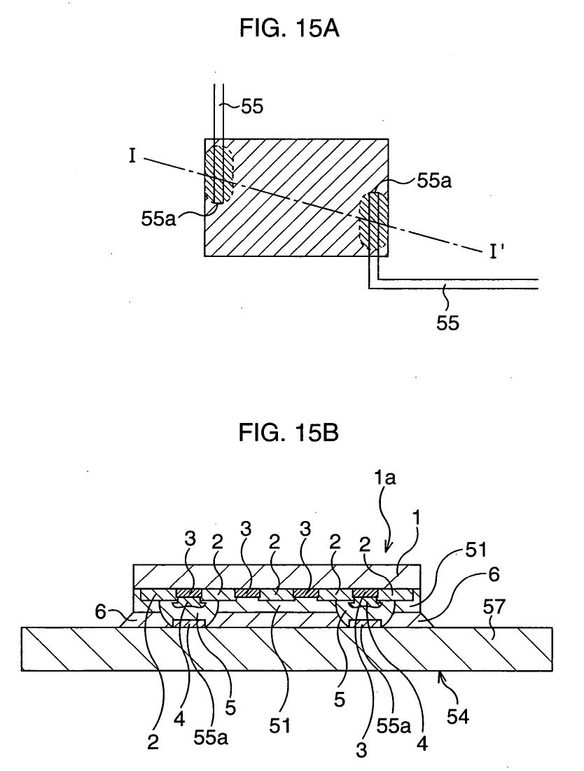

Subsequently, as shown in FIG. 14, the individual semiconductor chips 1a are cut out from a semiconductor wafer 20. This step is unnecessary, as a matter of course, if the individual semiconductor chips 1a are cut out before the cutting step. Then, as shown in FIG. 14 and FIG. 15, the semiconductor chip 1a and an RFID antenna part 54 are joined. Here, FIG. 15A represents an enlarged circle C in FIG. 14. FIG. 15B represents a cross section along I-I′ in FIG. 15A. In this RFID antenna part 54, an antenna 55 is formed in a coil shape on one surface of a substrate 57. On the antenna 55 antenna terminals 55a to be connected to the semiconductor chip 1a are formed.

As a material of the antenna, there is used a copper foil, a gold foil, an aluminum foil, a copper wire, a silver wire, a gold wire, a silver ink, a gold ink, a palladium ink or the like.

When the semiconductor chip 1a and the RFID antenna part 54 are joined, they are aligned in a manner that the electrodes 5 of the semiconductor chip 1a face the antenna terminals 55a of the RFID antenna part 54. Then, with temperatures of semiconductor chip 1a and the RFID antenna part 54 being higher than 110° C. which is a higher value of the softening temperatures for the electrodes 5 and the insulating film 6, i.e. the first temperature and the second temperature, and at the same time lower than 130° C. which is a lower value of solidifying (curing) temperatures for the electrodes 5 and the insulating film 6, i.e. the third temperature and the fourth temperature, the electrodes 5 are corresponded to the antenna terminals 55a. Then, the insulating film 6 is softened so that the insulating resin of the insulating film 6 fills between the electrodes 5 and the antenna terminals 55a, and the electrodes 5 and the antenna terminals 55a are contacted.

Here, since the electrodes 5 and the insulating film 6 can be recognized by reflectivities and hues of the respective surfaces, it is possible to utilize differences of the reflectivities and the hues to align the electrodes 5 and the antenna terminals 55a with a reflectivity measurement apparatus and a camera apparatus.

In such a state, the semiconductor chip 1a and the RFID antenna part 54 are pressed at and above a higher value of the third temperature and the fourth temperature, for example at 130° C. to 150° C., at a load of several gf per electrode, for example, at 10 gf, for a predetermined time, to cure the conductive material of the electrodes 5 and the insulating material of the insulating film 6. Then the temperature is further kept at 150° C. for approximately 30 minutes so that the conductive material and the insulating material are completely cured. Consequently, the semiconductor chip 1a and the RFID antenna part 54 are connected by the insulating film 6, and the electrodes 5 and the antenna terminals 55a are joined. At this time, the electrodes 5 and the antenna terminals 55a are electrically connected and conducted, as well as the insulating film 6 adheres securely due to excellent adhesiveness thereof so that the semiconductor chip 1a and the RFID antenna part 54 are securely joined.

Incidentally, in this case, it is also possible that the temperature of the semiconductor chip 1a is set to be lower than 80° C. which is the lower value of the respective softening temperatures for the electrode 5 and the insulating film 6 and the temperature of the RFID antenna part 54 is set to be higher than 110° C. which is the higher value of the respective softening temperatures for the electrodes 5 and the insulating film 6, and in this state the electrodes 5 and the antenna terminals 55a are corresponded and contacted, with the temperature of the electrodes 5 and insulating film 6 becoming at and above 110° C. so that the electrodes 5 and insulating film 6 are softened.

Thereafter, after formation of a protective film (not shown) and so on, the RFID or the non-contact IC card is completed.

As described above, according to the present embodiment, there can be formed an RFID or a non-contact IC card which is low in cost, has an even and smooth height, enables forming of metal terminals connected at a low load, enables mounting at low damage, and has high reliability. Further, when the electrodes 5 are formed, by forming in the photosensitive resin 51 the openings of an arbitrary size to reveal only the metal layers 3 of an arbitrary portion, it is possible to form the metal layers 4 only on the arbitrary metal layers 3 and to form the subsequent electrodes 5. Therefore, it is possible to choose only necessary metal layers 3 and form the electrodes 5, omitting unnecessary electrode formation so that the semiconductor chip can be manufactured effectively.

Incidentally, in the present embodiment, a case that the above cutting is performed only on one principal surface of the semiconductor chip 1a is exemplified. It is considered sufficient that the cutting is not performed on one principal surface of the RFID antenna part 54, on which the antenna terminals 55a are formed evenly to some extent. However, the one principal surface can also be planarized by the cutting as in the semiconductor chip 1a.

Meanwhile, the individual semiconductor chips 1a can be tested with a test terminal (not shown) in a stage, for example, that the metal layers 3 are formed on the semiconductor chip 1a. A semiconductor chip 1a judged to be defective as a result of a test can be distinguished from a non-defective semiconductor chip 1a by a release agent resin for hampering adhesion of the conductive resin being coated on its surface, so that the conductive resin fails to adhere to this semiconductor chip 1a only, when the Ag paste 11 being the material of the electrodes 5 is coated.

Similarly, the individual semiconductor chips 1a can be tested with the test terminal, in the stage, for example, that the metal layers 3 are formed on the semiconductor chip 1a. The semiconductor chip 1a judged to be defective as a result of the test can be distinguished from the non-defective semiconductor chip 1a, by a resin having a color tone different from that of the insulating film 6 being dropped in a center for example of the surface of the semiconductor chip 1a.

Meanwhile, it is preferable that, when the insulating film 6 is formed, a display area of the semiconductor chip 1a in the semiconductor wafer 20, for example, a serial number area, is masked with a tape (not shown) made of adhesive material which is not cured at the first temperature, and in this state the insulating film 6 is formed. Then, the tape is removed before application of the second temperature so that the serial number area is not covered by the insulating resin of the insulating film 6, to function as the display area.

In the present embodiment, there is exemplified a case that a single layer insulating film 6 is formed. However, two layers of insulating films can be formed as in the second embodiment, for example. In this case, the first insulting film and/or the second insulating film are/is opaque film(s).

According to the present invention, there can be obtained the joined base which is low in cost, has the even and smooth height, enables forming of the metal terminals connected at a low load, enables mounting at low damage, and has high reliability to prevent unauthorized alteration by detaching the base. Further, even if the insulator in the first base such as the semiconductor chip is opaque, the surfaces of the electrodes revealed by the cutting is recognizable. Therefore, the first base can be easily aligned to the second base such as the circuit board and mounted.

The present embodiments are to be considered in all respects as illustrative and no restrictive, and all changes which come within the meaning and range of equivalency of the claims are therefore intended to be embraced therein. The invention may be embodied in other specific forms without departing from the spirit or essential characteristics thereof.

What is clamed is:

1. A method for processing a base comprising the steps of:
forming an insulating film on a first base by depositing an insulating material exhibiting adhesiveness at and above a second temperature;
forming openings in the insulating film;
forming first electrodes by depositing a conductive material exhibiting adhesiveness at and above a first temperature in a manner that the conductive material fills inside the openings;
performing cutting with a cutting tool so that surfaces of the first electrodes and a surface of the insulating film are processed to be continuously planar, while temperature is kept under a lower temperature of the first temperature and the second temperature; and
raising temperature to and above a higher temperature of the first temperature and the second temperature, and making the first base face a second base on a surface of which a plurality of second electrodes are formed in a manner that the first electrodes contact the second electrodes, so that the first base and the second base are connected by the insulating film and so that electric connection is generated between the first electrodes and the second electrodes.

2. The method for processing the base according to claim 1,
wherein, the step of cutting is performed while temperatures to which the first electrodes and the insulating film are raised by friction heat generated in the cutting are kept under the lower temperature of the first temperature and the second temperature.

3. The method for processing the base according to claim 1,
wherein the conductive material is solid and does not exhibit adhesiveness at a room temperature, and softens and exhibits adhesiveness when reaching the first temperature, and
wherein the insulating material is solid and does not exhibit adhesiveness at the room temperature, and softens and exhibits adhesiveness when reaching the second temperature.

4. The method for processing the base according to claim 1, wherein the step of making the first base and the second base face each other and connected comprises the steps of:
setting a temperature of the first base to be under the lower value of the first temperature and the second temperature, and setting a temperature of the second base to be over the higher value of the first temperature and the second temperature; and
making the first electrodes and the second electrodes face and contact each other under the set temperatures so that temperatures of the insulating film and the first electrodes become at and above the higher value of the first temperature and the second temperature, to connect the first base and the second base.

5. The method for processing the base according to claim 1, wherein, in the step of making the first base and the second base face each other and connected,
connection of the first base and the second base by the insulating film, and connection of the first electrodes and the second electrodes, are performed simultaneously at and above the higher value of the first temperature and the second temperature.

6. The method for processing the base according to claim 1, wherein, in the step of making the first base and the second base face each other and connected,
the first electrodes and the second electrodes are made face and contact each other at a predetermined pressure at and above the higher value of the first temperature and the second temperature, so that the first electrodes are softened and connected to the second electrodes, and so that the insulating film is softened to fill between the first base and the second base, to connect the first base and the second base.

7. The method for processing the base according to claim 1,
wherein the conductive material solidifies and loses adhesiveness at and above a third temperature higher than the first temperature, and
wherein the insulating material is a thermosetting material which solidifies and loses adhesiveness at and above a fourth temperature higher than the second temperature.

8. The method for processing the base according to claim 1, wherein the first electrodes and the insulating film are recognized by reflectivities and hues of the respective surfaces after the surfaces of the first electrodes and the surface of the insulating film are planarization processed by the cutting.

9. The method for processing the base according to claim 8, wherein the first electrodes and the second electrodes are aligned by utilizing differences of the reflectivities and the hues, when the first base and the second base are connected.

10. The method for processing the base according to claim 1, wherein the insulating film is opaque, so that a surface of the first base is invisible due to the insulating film after the surfaces of the first electrodes and the surface of the insulating film are planarization processed by the cutting.

11. A method for processing a base comprising the steps of:
forming an insulating film on a first base by depositing an insulating material exhibiting adhesiveness at and above a second temperature;
forming openings in the insulating film;
forming first electrodes by depositing a conductive material exhibiting adhesiveness at and above a first temperature in a manner that the conductive material fills inside the openings;
performing cutting with a cutting tool so that surfaces of the first electrodes and a surface of the insulating film are processed to be continuously planar, while temperature is kept under a lower temperature of the first temperature and the second temperature; and
raising temperature to and above a higher value of the first temperature and the second temperature, and making the first base face a second base on a surface of which a plurality of second electrodes are formed in a manner that the first electrodes contact the second electrodes, so that the first base and the second base are connected by the insulating film and so that electric connection is generated between the first electrodes and the second electrodes.

12. The method for processing the base according to claim 11, wherein the insulating film has photosensitivity, and the openings are formed by selectively exposing the insulating film.

13. The method for processing the base according to claim 11, wherein the step of cutting is performed while temperatures to which the first electrode and the insulating film are raised by friction heat generated in the cutting are kept under the lower temperature of the first temperature and the second temperature.

14. The method for processing the base according to claim 11,
wherein the conductive material is solid and does not exhibit adhesiveness at a room temperature, and softens and exhibits adhesiveness when reaching the first temperature, and
wherein the insulating material is solid and does not exhibit adhesiveness at the room temperature, and softens and exhibits adhesiveness when reaching the second temperature.

15. The method for processing the base according to claim 11, wherein the step of making the first base and the second base face each other and connected comprises the steps of:
setting a temperature of the first base to be under the lower value of the first temperature and the second temperature, and setting a temperature of the second base to be over the higher value of the first temperature and the second temperature; and
making the first electrodes and the second electrodes face and contact each other under the set temperatures so that temperatures of the insulating film and the first electrode become at and above the higher value of the first temperature and the second temperature, to connect the first base and the second base.

16. The method for processing the base according to claim 11, wherein, in the step of making the first base and the second base face each other and connected,
connection of the first base and the second base by the insulating film, and connection of the first electrodes and the second electrodes, are performed simultaneously at and above the higher value of the first temperature and the second temperature.

17. The method for processing the base according to claim 11, wherein, in the step of making the first base and the second base face each other and connected,
the first electrodes and the second electrodes are made face and contact each other at a predetermined pressure at and above the higher value of the first temperature and the second temperature, so that the first electrodes are softened and connected to the second electrodes, and so that the insulating film is softened to fill between the first base and the second base, to connect the first base and the second base.

18. The method for processing the base according to claim 11, wherein the conductive material and the insulating material respectively solidify and lose adhesiveness at and above the third temperature higher than the first and the second temperature.

19. The method for processing the base according to claim 11, wherein the first electrodes and the insulating film are recognized by reflectivities and hues of the respective surfaces after the surfaces of the first electrodes and the surface of the insulating film are planarization processed by the cutting.

20. The method for processing the base according to claim 19, wherein the first electrodes and the second electrodes are aligned by utilizing differences of the reflectivities and the hues, when the first base and the second base are connected.

21. The method for processing the base according to claim 11, wherein the insulating film is opaque so that a surface of the first base is invisible due to the insulating film after the surfaces of the first electrodes and the surface of the insulating film are planarization processed by the cutting.

22. A method for processing a base, comprising the steps of:
forming first electrodes with projecting shapes, on a surface of a first base, with a conductive material exhibiting adhesiveness at and above a first temperature;
coating a first insulating film made of a first insulating material exhibiting adhesiveness at and above a second temperature, on a surface of the first base, in a manner to be lower than heights of the first electrodes;
coating a second insulating film made of a second insulating material exhibiting adhesiveness at and above a third temperature, on the first insulating film including on the first electrodes;
performing cutting with a cutting tool so that surfaces of the first electrodes and a surface of the second insulating film are processed to be continuously planar, while temperature is kept under a lowest value of the first temperature, the second temperature, and the third temperature;
disposing a second base on which second electrodes corresponding to the first electrodes are formed, on the surface on which the first electrodes are formed, of the first base, in a manner that the first base and the second base face each other; and
raising temperature to and above a highest value of the first temperature, the second temperature, and the third temperature, so that the first base and the second base are connected by the insulating films composed of the first insulating film and the second insulating film, and so that the first electrodes and the second electrodes are electrically connected.

23. The method for processing the base according to claim 22,
wherein the first insulating material is a material exhibiting adhesive intensity with the first base at and above a fourth temperature, and
wherein the second insulating material is a material exhibiting adhesive intensity with both the first insulating material and the second base at and above a fifth temperature.

24. The method for processing the base according to claim 22, wherein the step of cutting is performed while temperatures to which the first electrodes and the insulating films are raised by friction heat generated in the cutting are kept under the lowest value of the first temperature, the second temperature, and the third temperature.

25. The method for processing the base according to claim 22,
wherein the conductive material is solid and does not exhibit adhesiveness at a room temperature, and softens and exhibits adhesiveness when reaching the first temperature,
wherein the first insulating material is solid and does not exhibit adhesiveness at the room temperature, and softens and exhibits adhesiveness when reaching the second temperature, and
wherein the second insulating material is solid and does not exhibit adhesiveness at the room temperature, and softens and exhibits adhesiveness when reaching the third temperature.

26. The method for processing the base according to claim 22, wherein the step of making the first base and the second base face each other and connected comprises the steps of:
setting a temperature of the first base to be under the lowest value of the first temperature, second temperature, and the third temperature, and setting a temperature of the second base to be over the highest value of the first temperature, the second temperature, and the third temperature; and
making the first electrodes and the second electrodes face and contact each other under the set temperatures so that temperatures of the insulating films and the first electrodes become to and above the highest value of the first temperature, the second temperature, and the third temperature, to connect the first base and the second base.

27. The method for processing the base according to claim 22, wherein, in the step of making the first base and the second base face each other and connected,
connection of the first base and the second base by the insulating films, and connection of the first electrodes and the second electrodes, are performed simultaneously at and above the highest value of the first temperature, the second temperature, and the third temperature.

28. The method for processing the base according to claim 22, wherein, in the step of making the first base and the second base face each other and connected,
the first electrodes and the second electrodes are made face and contact each other at a predetermined pressure at and above the highest value of the first temperature, the second temperature, and the third temperature, so that the first electrodes are softened and connected to the second electrodes, and so that the second insulating film is softened to fill between the first base and the second base, to connect the first base and the second base.

29. The method for processing the base according to claim 22,
wherein the conductive material solidifies and loses adhesiveness at and above a sixth temperature higher than the first temperature,
wherein the first insulating material solidifies and loses adhesiveness at and above a fourth temperature higher than the first temperature, and
wherein the second insulating material solidifies and loses adhesiveness at and above a fifth temperature higher than the first temperature.

30. The method for processing the base according to claim 29, wherein a viscosity of the conductive material at and above the first temperature and under the sixth temperature is higher than a viscosity of the first insulating material at and above the second temperature and at and under the fourth temperature, and than a viscosity of the second insulating material at and above the third temperature and at and under the fifth temperature.

31. The method for processing the base according to claim 22,
wherein the conductive material is a material which is not cured and keeps adhesiveness even after being exposed more than once to a temperature not lower than the first temperature and lower than the sixth temperature,
wherein the first insulating material is a material which is not cured and keeps adhesiveness even after being exposed more than once to a temperature not lower than the second temperature and lower than the fourth temperature, and
wherein the second insulating material is a material which is not cured and keeps adhesiveness even after being exposed more than once to a temperature not lower than the third temperature and lower than the fifth temperature.

32. The method for processing the base according to claim 22, wherein the second electrodes formed in the second base are formed in substantially the same planar as insulating portion between the second electrodes.

33. The method for processing the base according to claim 22, wherein the first electrodes and the second insulating film are recognizable by reflectivities and hues of the respective surfaces after the surfaces of the first electrodes and the surface of the second insulating film are planarization processed by the cutting.

34. The method for processing the base according to claim 33, wherein the first electrodes and the second electrodes are aligned by utilizing differences of the reflectivities and the hues, when the first base and the second base are connected.

35. The method for processing the base according to claim 22, wherein the first insulating film and/or the second insulating film are/is opaque so that a surface of the first base is invisible due to the first insulating film and/or the second insulating film after the surfaces of the first electrodes and the surface of the second insulating film are planarization processed by the cutting.

36. The method for processing the base according to claim 22, wherein the first electrode is made of at least one kind of materials of gold, tin, copper, silver, aluminum, and nickel, or made of an alloy thereof.

37. A method for processing a base, with regard to a first base on a surface of which a plurality of foundation electrodes are formed and first electrodes are projectingly formed on the arbitrary foundation electrodes, the method comprising the steps of:
forming a first insulating film by filling a first insulating material between the first electrodes in a manner to be lower than heights of the first electrodes, and then forming a second insulating film by depositing a second insulating material on the first insulating film in a manner to cover the first electrodes, with use of the first insulating material exhibiting adhesiveness at and above a first temperature and the second insulating material exhibiting adhesiveness at and above a second temperature;
performing cutting with a cutting tool so that surfaces of the first electrodes and a surface of the second insulating film are planarization processed to be continuously planar, while temperature is kept under a lower value of the first temperature and the second temperature; and
raising temperature to and above a higher temperature of the first temperature and the second temperature, and making the first base face a second base on a surface of which a plurality of second electrodes are formed, in a manner that the first electrodes contact the second electrodes, so that the first base and the second base are connected by the second insulating film and so that electric connection is generated between the first electrodes and the second electrodes.

38. The method for processing the base according to claim 37,
wherein the first insulating material is a material which exhibits adhesiveness to the first base at and above a third temperature, and
wherein the second insulating material is a material which exhibits adhesiveness to both the first insulating material and the second base at and above a fourth temperature.

39. A joined base comprising:
a first base on a surface of which a plurality of foundation electrodes are formed and first electrodes are projectingly formed on the arbitrary foundation electrodes, and which includes a first insulating film filling between the first electrodes in a manner to be lower than heights of the first electrodes and a second insulating film formed on the first insulating film in a manner to cover the first electrodes, with surfaces of the first electrodes and a surface of the second insulating film being made continuously planar by cutting; and
a second base on a surface of which a plurality of second electrode are formed,
wherein the first insulating film is made of an insulating material exhibiting adhesiveness to the first base at and above a first temperature, and the second insulating film is made of a material exhibiting adhesiveness to both the first insulating material and the second base at and above a second temperature, and
wherein the first base and the second base are joined by the second insulating film and become integrated, and the first electrodes and the second electrodes are electrically connected.
